(19) United States
(12) Patent Application Publication
(10) Pub. No.: US 2026/0293094 A1
(43) Pub. Date: Sep. 24, 2026

(54) SEMICONDUCTOR DEVICES INCLUDING VERTICAL CHANNEL TRANSISTORS

(71) Applicant: SAMSUNG ELECTRONICS CO., LTD., Suwon-si (KR)

(72) Inventors: Minseo YOON, Suwon-si (KR); Kwangmin PARK, Suwon-si (KR); Dongho AHN, Suwon-si (KR); Sechung OH, Suwon-si (KR); Jinwoo LEE, Suwon-si (KR); Jinmyung CHOI, Suwon-si (KR); Hideki HORII, Suwon-si (KR)

(73) Assignee: SAMSUNG ELECTRONICS CO., LTD., Suwon-si (KR)

(21) Appl. No.: 19/553,678

(22) Filed: Mar. 2, 2026

(30) Foreign Application Priority Data
Mar. 20, 2025 (KR) 10-2025-0036216

(51) Int. Cl. H10B 12/00

(52) U.S. Cl. CPC H10B 12/315; H10B 12/05; H10B 12/50

(57) ABSTRACT

A semiconductor device including bit lines arranged on a substrate and extending in a first horizontal direction, an active pattern that extends in a vertical direction on each of the bit lines and includes a first end facing the bit lines and a second end opposite to the first end, a cell capacitor arranged on the second end of the active pattern, and an anti-oxidation film pattern arranged between the first end of the active pattern and each of the bit lines and extending in the first horizontal direction on a top surface of each of the bit lines, wherein the anti-oxidation film pattern includes an oxide semiconductor including indium, and a first dopant included in the oxide semiconductor, and the first dopant includes at least one of magnesium (Mg), tantalum (Ta), fluorine (F), or nitrogen (N).

### CROSS-REFERENCE TO RELATED APPLICATION

This application is based on and claims priority under 35 U.S.C. § 119 to Korean Patent Application No. 10-2025-0036216, filed on Mar. 20, 2025, in the Korean Intellectual Property Office, the disclosure of which is incorporated by reference herein in its entirety.

### BACKGROUND

The present disclosure relates to a semiconductor device, and more particularly, to a semiconductor device including a vertical channel transistor.

In accordance with the downscaling of semiconductor devices, the size of dynamic random-access memory (DRAM) devices is also being reduced. In a DRAM device with a one transistor-one capacitor (1T-1C) structure in which one capacitor is connected to one transistor, there is a problem in which the leakage current through a channel region gradually increases as the device is miniaturized. In order to reduce leakage current, a vertical channel transistor using an oxide semiconductor material as a channel layer has been proposed.

### SUMMARY

The present disclosure provides a semiconductor device having excellent electrical performance.

According to an aspect of the present disclosure, there is provided a semiconductor device including bit lines arranged on a substrate and extending in a first horizontal direction, an active pattern extending in a vertical direction on each of the bit lines and including a first end facing the bit line and a second end opposite to the first end, a cell capacitor arranged on the second end of the active pattern, and an anti-oxidation film pattern arranged between the first end of the active pattern and each of the bit lines and extending in the first horizontal direction on a top surface of each of the bit lines, wherein the anti-oxidation film pattern includes an oxide semiconductor including indium, and a first dopant included in the oxide semiconductor, and the first dopant includes at least one of magnesium (Mg), tantalum (Ta), fluorine (F), or nitrogen (N).

According to an aspect of the present disclosure, there is provided a semiconductor device including a plurality of bit lines arranged on a substrate, extending parallel to each other, and extending in a first horizontal direction, a plurality of anti-oxidation film patterns arranged on the plurality of bit lines, extending parallel to each other, and extending in the first horizontal direction, a plurality of mold structures arranged on the plurality of anti-oxidation film patterns and extending in the second horizontal direction, a plurality of active patterns including a first end and a second end opposite to the first end, the first end being arranged on the sidewall of each of the plurality of mold structures and facing each of the anti-oxidation film pattern, and a plurality of cell capacitors arranged on the second ends of the plurality of active patterns, respectively, wherein a constituent material of the anti-oxidation film pattern is represented by a chemical formula of [InₓGa_{y}Zn_{z}O_{1.5}]₁₋ᵤXᵤ, where 0.9≤x≤1, 0≤y≤0.1, 0≤z≤0.1, x+y+z=1, X may be at least one of Mg, Ta, F, or N, and 0<u≤0.1.

According to an aspect of the present disclosure, there is provided a semiconductor device including a substrate, a peripheral circuit arranged on the substrate, bit lines that are arranged at a higher vertical level than the peripheral circuit on the substrate and extends in a first horizontal direction, an active pattern that extends in a vertical direction on each of the bit lines and includes a first end facing the bit lines and a second end opposite to the first end, a cell capacitor arranged on the second end of the active pattern, and an anti-oxidation film pattern arranged between the first end of the active pattern and each of the bit lines and extending in the first horizontal direction on a top surface of each of the bit lines, wherein a constituent material of the anti-oxidation film pattern is represented by a chemical formula of [InₓGa_{y}Zn_{z}O_{1.5}]₁₋ᵤXᵤ, where 0.9≤x≤1, 0≤y≤0.1, 0≤z≤0.1, x+y+z=1, and X may be at least one of Mg, Ta, F, or N, and 0<u≤0.1.

According to an aspect of the present disclosure, there is provided a method of manufacturing a semiconductor device including forming bit lines extending in a first horizontal direction on a substrate, forming anti-oxidation film patterns extending in the first horizontal direction on the bit lines, forming mold structures extending in a second horizontal direction on the anti-oxidation film patterns, forming an active pattern on the sidewall of each of the mold structures, and forming a cell capacitor on a top surface of the active pattern, wherein the anti-oxidation film pattern includes an oxide semiconductor including indium, and a first dopant included in the oxide semiconductor, and the first dopant includes at least one of magnesium (Mg), tantalum (Ta), fluorine (F), or nitrogen (N).

In embodiments, a constituent material of the anti-oxidation film pattern is represented by a chemical formula of [InₓGa_{y}Zn_{z}O_{1.5}]₁₋ᵤXᵤ, where 0.9≤x≤1, 0≤y≤0.1, 0≤z≤0.1, x+y+z=1, and X may be at least one of Mg, Ta, F, or N, and 0<u≤0.1.

In embodiments, the anti-oxidation film pattern further includes oxygen vacancies, and the oxygen vacancies may be included in an amount of 1 to 19 atomic percent with respect to a total atomic content of components constituting the anti-oxidation film pattern.

In embodiments, the active pattern may include a vertical extension portion extending in a vertical direction on the sidewall of the mold structure, and a horizontal extension portion connected to a bottom part of the vertical extension portion and extending in the first horizontal direction.

In embodiments, in the forming of the active pattern, the active pattern may be formed on a part of the anti-oxidation film pattern not covered by the mold structure, and the top surface of each of the bit lines may not be exposed to a process atmosphere for forming the active pattern.

In embodiments, the method may further include forming a gate insulation layer on a sidewall of the active pattern, and forming a word line facing the sidewall of the active pattern on the gate insulation layer.

In embodiments, the forming of the anti-oxidation film pattern may be performed by a physical vapor deposition (PVD) process.

In embodiments, the forming of the anti-oxidation film pattern may be performed by a sputtering process using a sputtering target including indium oxide or indium gallium zinc oxide.

In embodiments, in the forming of the anti-oxidation film pattern, the first dopant may be included in the sputtering target.

In embodiments, in the forming of the anti-oxidation film pattern, a carrier gas including the first dopant may be used.

### BRIEF DESCRIPTION OF THE DRAWINGS

Embodiments will be more clearly understood from the following detailed description taken in conjunction with the accompanying drawings in which:

FIG. 1 is a perspective view schematically illustrating a semiconductor device according to embodiments;

FIG. 2 is an enlarged layout diagram of a portion of a cell array region of FIG. 1;

FIG. 3 is a cross-sectional view taken along line A1-A1′ of FIG. 2;

FIG. 4 is a cross-sectional view taken along line A2-A2′ of FIG. 2;

FIG. 5 is an enlarged view of a portion EN1 of FIG. 3;

FIG. 6 is an enlarged view of a portion EN2 of FIG. 3;

FIG. 7 is a ternary diagram illustrating a composition of an anti-oxidation film pattern according to embodiments;

FIGS. 8 and 9 are cross-sectional views illustrating a semiconductor device according to embodiments;

FIG. 10 is an enlarged view of a portion EN2 of FIG. 9;

FIG. 11 is a cross-sectional view illustrating a semiconductor device according to embodiments;

FIG. 12 is an enlarged view of a portion EN2 of FIG. 11;

FIG. 13 is a cross-sectional view illustrating a semiconductor device according to embodiments;

FIG. 14 is a cross-sectional view illustrating a semiconductor device according to embodiments;

FIG. 15 is a cross-sectional view illustrating a semiconductor device according to embodiments; and

FIGS. 16, 17A, 17B, 17C, 18A, 18B, 18C, 19A, 19B, 19C, 20A, 20B, 21A, 21B, 22A, 22B, 23A, 23B, 23C, 24A, 24B, and 24C are schematic diagrams illustrating a method of manufacturing a semiconductor device according to embodiments.

### DETAILED DESCRIPTION OF THE EMBODIMENTS

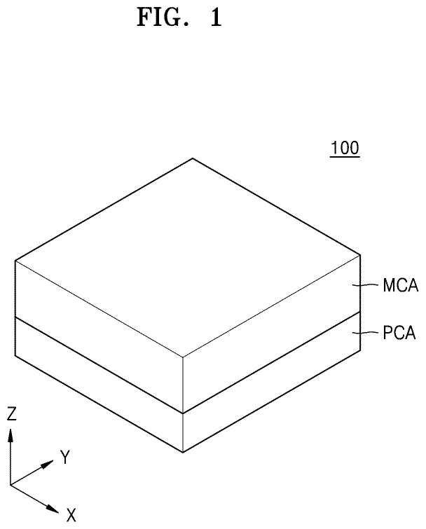

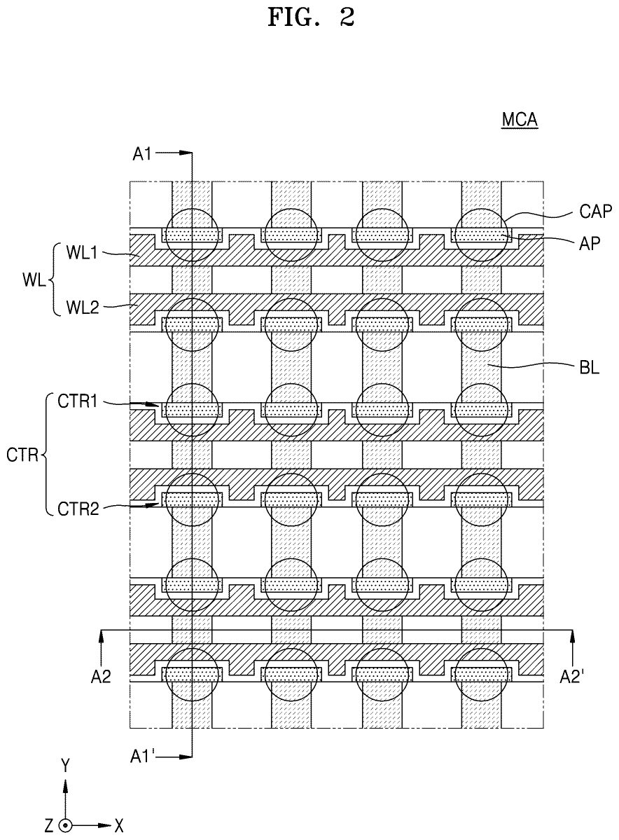

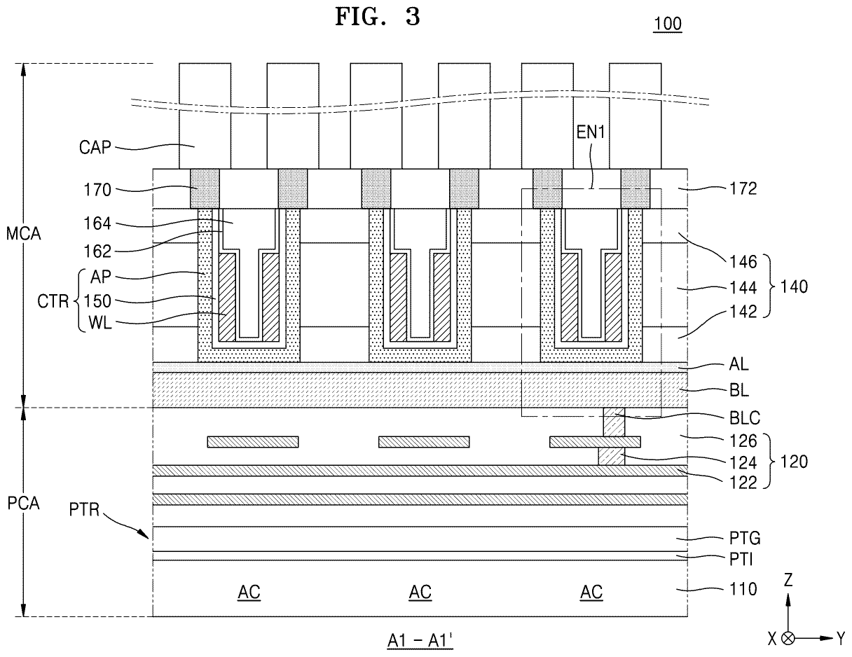

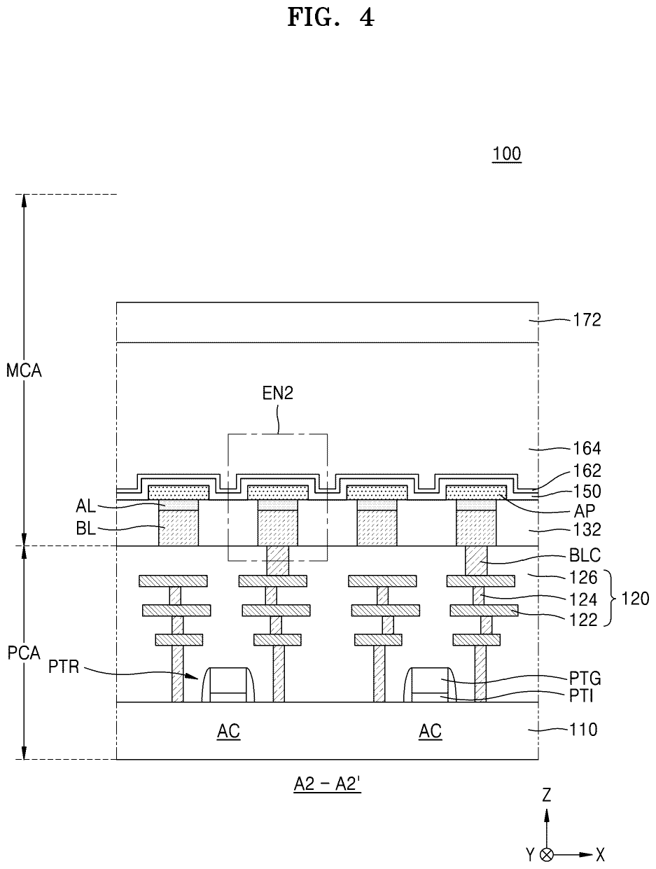

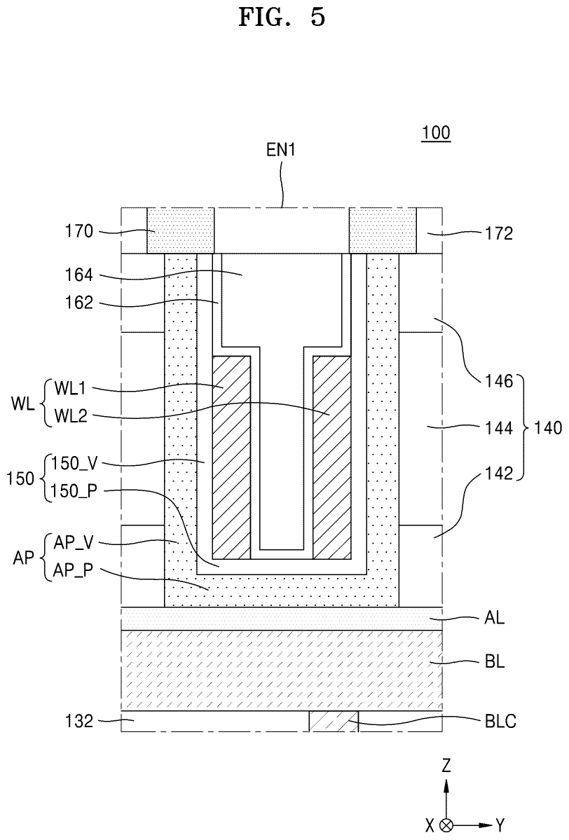

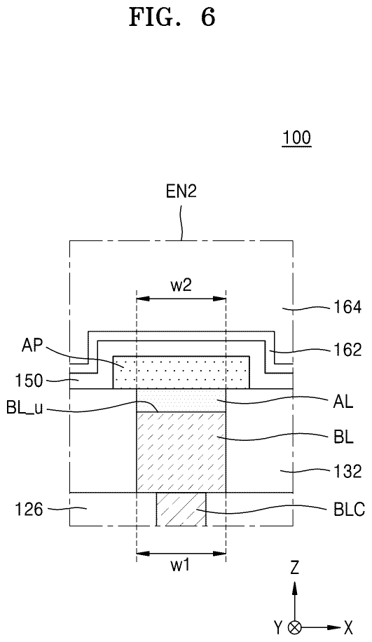

FIG. 1 is a perspective view schematically illustrating a semiconductor device 100 according to embodiments. FIG. 2 is an enlarged layout diagram of a portion of a cell array region MCA of FIG. 1. FIG. 3 is a cross-sectional view taken along line A1-A1′ of FIG. 2. FIG. 4 is a cross-sectional view taken along line A2-A2′ of FIG. 2. FIG. 5 is an enlarged view of a portion EN1 of FIG. 3. FIG. 6 is an enlarged view of a portion EN2 of FIG. 3.

Referring to FIGS. 1 to 6, a semiconductor device 100 may include a peripheral circuit region PCA and a cell array region MCA arranged at a vertical level higher than the peripheral circuit region PCA.

In some embodiments, the cell array region MCA may be a memory cell region of a dynamic random access memory (DRAM) device, and the peripheral circuit region PCA may be a core region or a peripheral circuit region of the DRAM device. For example, the peripheral circuit region PCA may include a peripheral circuit transistor (PTR) for transmitting signals and/or power to a memory cell array included in the cell array region MCA. In embodiments, the peripheral circuit transistor PTR may configure various circuits such as a command decoder, control logic, address buffer, row decoder, column decoder, sense amplifier, data input/output circuit, and the like.

A plurality of word lines WL extending in a first horizontal direction X and a plurality of bit lines BL extending in a second horizontal direction Y may be arranged in the cell array region MCA. A plurality of cell transistors CTR may be arranged at intersections of the plurality of word lines WL and the plurality of bit lines BL. A plurality of cell capacitors CAP may be arranged on the plurality of cell transistors CTR, respectively.

The plurality of word lines WL may include a first word line WL1 and a second word line WL2 alternately arranged in the second horizontal direction Y, and the plurality of cell transistors CTR may include a first cell transistor CTR1 and a second cell transistor CTR2 alternately arranged in the second horizontal direction Y. The first cell transistor CTR1 may be arranged adjacent to the first word line WL1, and the second cell transistor CTR2 may be arranged adjacent to the second word line WL2. The first cell transistor CTR1 and the second cell transistor CTR2 may have a mirror symmetrical structure with respect to each other. For example, the first cell transistor CTR1 and the second cell transistor CTR2 may have a mirror symmetrical structure with respect to the center line between the first cell transistor CTR1 and the second cell transistor CTR2 extending in the first horizontal direction X.

Although not shown, an edge region may be arranged around the cell array region MCA. The edge region may be a region in which an electrical connection member to each of the word lines WL and/or an electrical connection member to each of the bit lines BL are arranged, and may be a region in which electrical connection members enabling electrical connection between the cell array region MCA and the peripheral circuit region PCA are arranged.

Hereinafter, as shown in FIGS. 3 and 4, a case where the cell array region MCA is arranged at a vertical level higher than the peripheral circuit region PCA (e.g., when the cell array region MCA is arranged on the peripheral circuit region PCA) will be described. However, the semiconductor device 100 may be upside down so that the cell array region MCA is located at a lower vertical level than the peripheral circuit region PCA. In this case, the “top surfaces” or “bottom surfaces” of the components in the following description shall be understood to refer to the “bottom surfaces” or “top surfaces” of the components, respectively. The components described as being “up” or “down” in any component shall be understood as being “down” or “up” in any component, respectively. Components described as “positioned at a higher vertical level” should be understood as “positioned at a lower vertical level.”.

In embodiments, the substrate 110 may include silicon, for example, single crystalline silicon, polycrystalline silicon, or amorphous silicon. In some other embodiments, the substrate 110 may include at least one selected from Ge, SiGe, SiC, GaAs, InAs, and InP. In some embodiments, the substrate 110 may include a conductive region, such as an impurity-doped well or an impurity-doped structure.

In the peripheral circuit region PCA, an active region AC may be defined in the substrate 110, and a peripheral circuit transistor PTR may be arranged on the active region AC of the substrate 110. The peripheral circuit transistor PTR may include a gate electrode PTG and a gate insulation layer PTI. Source/drain regions may be arranged at both sides of a gate electrode PTG and in upper portions of the substrate 110.

A peripheral circuit wiring structure 120 may be arranged on the substrate 110. The peripheral circuit wiring structure 120 may include a peripheral circuit wiring 122, a peripheral circuit contact 124, and a peripheral circuit insulation layer 126. The peripheral circuit wiring 122 and the peripheral circuit contact 124 may be electrically connected to the peripheral circuit transistor PTR and/or the substrate 110, and the peripheral circuit insulation layer 126 may cover the peripheral circuit transistor PTR, the peripheral circuit wiring 122, and the peripheral circuit contact 124 on the substrate 110. The peripheral circuit insulation layer 126 may include an oxide film, a nitride film, a low-k dielectric film, or a combination thereof, and may be formed in a stacked structure of a plurality of insulation layers.

The cell array region MCA may be arranged on the peripheral circuit wiring structure 120. In the cell array region MCA, the plurality of bit lines BL, the plurality of cell transistors CTR, and the plurality of cell capacitors CAP may be sequentially arranged in a vertical direction Z. For example, the plurality of bit lines BL may be arranged on the peripheral circuit wiring structure 120, the plurality of cell transistors CTR may be arranged on the plurality of bit lines BL, and the plurality of cell capacitors CAP may be arranged on the plurality of cell transistors CTR. In embodiments, the bit lines BL may be arranged closer to the top surface of the substrate 110 than the cell transistors CTR or the cell capacitors CAP. Accordingly, a vertical distance between the bit line BL and the peripheral circuit transistor PTR may be less than a vertical distance between the cell capacitor CAP and the peripheral circuit transistor PTR.

In embodiments, the plurality of bit lines BL may extend in the second horizontal direction Y. The bit lines BL may include Ti, TiN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof. A first insulation layer 132 may be arranged between the plurality of bit lines BL. The first insulation layer 132 may fill a space between the plurality of bit lines BL, and may have a plurality of line pattern shapes extending in the second horizontal direction Y between the plurality of bit lines BL.

In embodiments, a bit line contact BLC may be arranged between the bottom surface of the bit line BL and the peripheral circuit line 122. The bit line BL may be electrically connected to the peripheral circuit transistor PTR by the bit line contact BLC.

In embodiments, a plurality of anti-oxidation film patterns AL may be arranged on top surfaces of the plurality of bit lines BL, respectively. The plurality of anti-oxidation film patterns AL cover the top surfaces of the plurality of bit lines BL, respectively, and may extend in the second horizontal direction Y. In embodiments, each anti-oxidation film pattern AL may cover the entirety of the top surface BL_u of the corresponding bit line BL, a first portion of the anti-oxidation film pattern AL may be arranged between the top surface BL_u of the bit line BL and the cell transistor CTR, and a second portion of the anti-oxidation film pattern AL may be arranged between the top surface BL_u of the bit line BL and the mold structure 140.

In embodiments, the anti-oxidation film pattern AL may include an indium-rich oxide semiconductor. Here, the indium-rich oxide semiconductor may refer to an oxide containing indium in a relatively high content. In embodiments, the anti-oxidation film pattern AL may include an oxide semiconductor represented by chemical formula of InₓGa_{y}Zn_{z}O_{1.5} (0.9≤x≤1, 0≤y≤0.1, 0≤z≤0.1, and x+y+z=1).

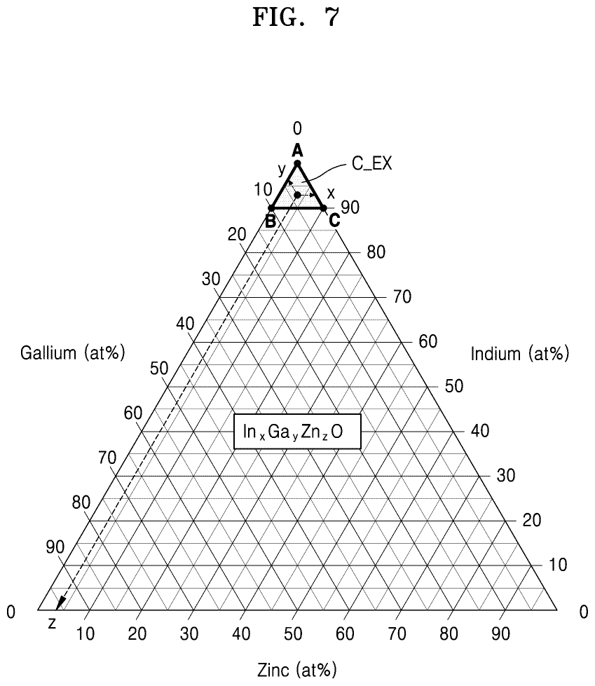

FIG. 7 is a ternary diagram illustrating a composition of an anti-oxidation film pattern AL according to embodiments. As shown in FIG. 7, the anti-oxidation film pattern AL may include an indium-rich oxide semiconductor that falls within a content range C_EX, for example, an oxide semiconductor that includes indium, gallium, and zinc as cations. For example, the content range C_EX may refer to a triangle defined by points A, B, and C, and each of the points A, B, and C may represent the relative content of the three cations included in the oxide: indium, gallium, and zinc. Point A may indicate a composition in which indium content is 100% among the three cations, that is, indium oxide (InO_{1.5}). Point B may indicate a composition corresponding to 90% of indium content and 10% of gallium content among the three cations, that is, indium gallium oxide (In_{0.9}Ga_{0.1}O_{1.5}). Point C may indicate a composition corresponding to 90% of indium content and 10% of zinc content among the three cations, that is, indium zinc oxide (In_{0.9}Zn_{0.1}O_{1.5}).

In embodiments, the anti-oxidation film pattern AL may include an indium-rich oxide semiconductor having a composition at any point within the content range C_EX, and with respect to a total number of atoms of indium, gallium, and zinc, indium may be included in a ratio of 90 to 100 atomic percent, gallium may be included in a ratio of 0 to 10 atomic percent, and zinc may be included in a ratio of 0 to 10 atomic percent.

In embodiments, the anti-oxidation film pattern AL may further include a first dopant added to the indium-rich oxide semiconductor. In embodiments, the first dopant may include at least one of magnesium (Mg), tantalum (Ta), fluorine (F), or nitrogen (N). The first dopant may be included in a predetermined concentration in the indium-rich oxide semiconductor having a composition at any point within the content range C_EX.

In embodiments, the anti-oxidation film pattern AL may have a composition including a first dopant in an amount of more than 0 and less than or equal to 10 atomic percent (at %), with an oxide represented by a chemical formula of InₓGa_{y}Zn_{z}O_{1.5} (0.9≤x≤1, 0≤y≤0.1, 0≤z≤0.1, and x+y+z=1) as a starting composition. In embodiments, the anti-oxidation film pattern AL is represented by a chemical formula of [InₓGa_{y}Zn_{z}O_{1.5}]₁₋ᵤXᵤ, where 0.9≤x≤1, 0≤y≤0.1, 0≤z≤0.1, x+y+z=1, X may be at least one of Mg, Ta, F, or N, and 0<u≤0.1.

In some embodiments, the anti-oxidation film pattern AL may not substantially include gallium atoms and zinc atoms, and the anti-oxidation film pattern AL may include indium oxide to which a first dopant is added. The anti-oxidation film pattern AL may include an indium-based oxide represented by a formula of [InₓO_{y}]₁₋ᵤXᵤ (0.38≤x≤0.42, 0.58≤y≤0.62, X is at least one of Mg, Ta, F, or N, and 0<u≤0.1). In some embodiments, the anti-oxidation film pattern AL may include indium oxynitride (InₓO_{y}N_{z}).

In embodiments, the anti-oxidation film pattern AL may include oxygen vacancies. In other words, the anti-oxidation film pattern AL includes an indium-rich oxide semiconductor having a composition at any point within the content range C_EX, and some of the oxygen atoms included in the indium-rich oxide semiconductor may be substituted with oxygen vacancies. In some examples, oxygen vacancies may be included in an amount of 1 to 19 atomic percent with respect to [InₓGa_{y}Zn_{z}O_{1.5}]₁₋ᵤXᵤ.

In embodiments, a sidewall of the anti-oxidation film pattern AL may be aligned with a sidewall of the bit line BL and a sidewall of the anti-oxidation film pattern AL may be in contact with the first insulation layer 132. The bit line BL may have a first width w1 in the first horizontal direction X, and a portion of the anti-oxidation film pattern AL arranged on each bit line BL may have a second width w2 in the first horizontal direction X. In embodiments, the second width w2 may be substantially the same as the first width w1. In embodiments, the anti-oxidation film pattern AL may have a thickness of 1 to 50 angstroms in the vertical direction Z.

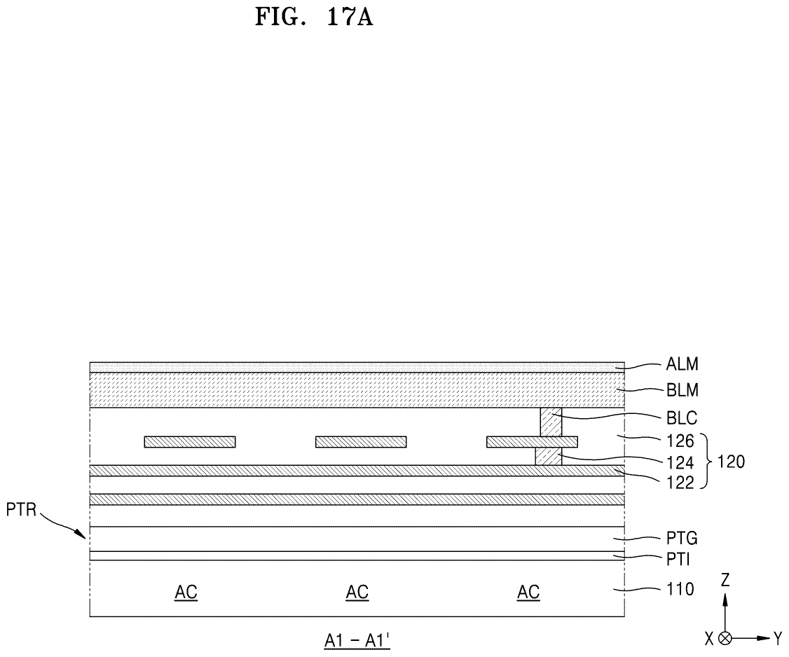

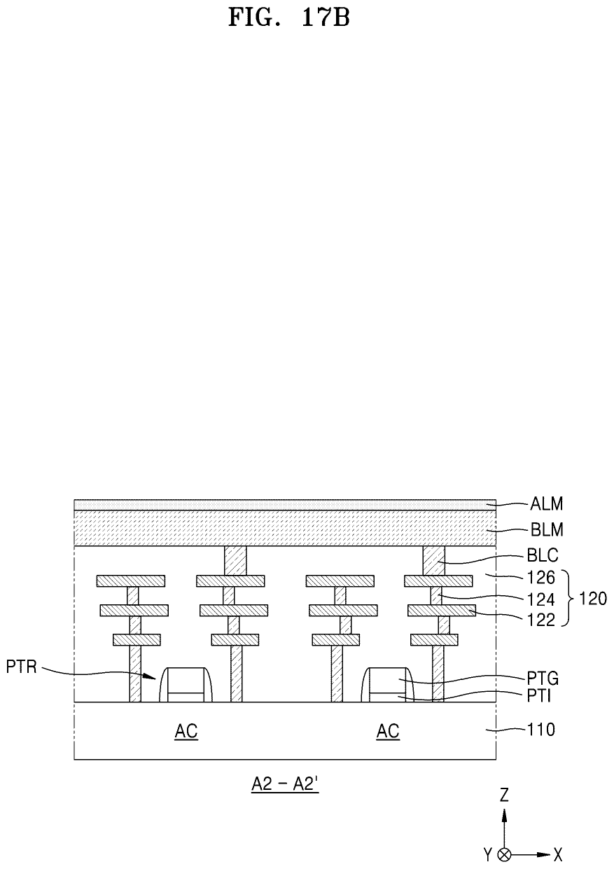

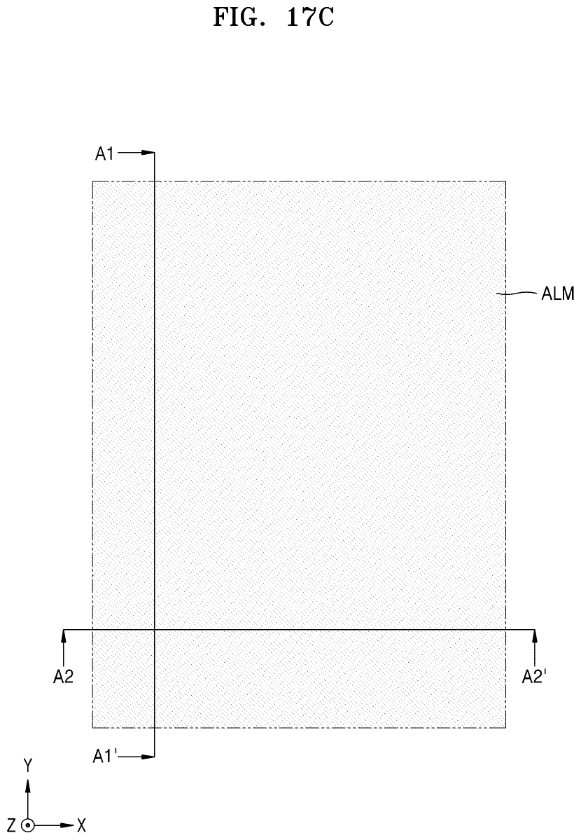

In embodiments, a bit line material layer BLM (see FIG. 17A) may be first formed, an anti-oxidation film material layer ALM (see FIG. 17A) may be formed on the bit line material layer BLM, and then the anti-oxidation film material layer ALM and the bit line material layer BLM may be patterned using a mask pattern to form an anti-oxidation film pattern AL and a bit line BL. Here, the feature in which the second width w2 of the anti-oxidation film pattern AL is substantially the same as the first width w1 of the bit line BL may mean that one value falls within the range of 90% to 110% of the other value in consideration of errors or tolerances that occur when the bit line BL and the anti-oxidation film pattern AL are manufactured in the same process.

A plurality of mold structures 140 and a plurality of cell transistors CTR may be arranged on the anti-oxidation film pattern AL and the first insulation layer 132. For example, each of the plurality of mold structures 140 may extend in the first horizontal direction X, and the plurality of cell transistors CTR may be arranged on both sidewalls of each mold structure 140.

Each of the plurality of mold structures 140 may include a first mold layer 142, a second mold layer 144, and a third mold layer 146 arranged in the vertical direction Z. For example, the first mold layer 142 may be arranged on the anti-oxidation film pattern AL and the first insulation layer 132, the second mold layer 144 may be arranged on the first mold layer 142, and the third mold layer 146 may be arranged on the second mold layer 144.

In embodiments, each of the first to third mold layers 142, 144, and 146 may include at least one of silicon oxide, silicon nitride, silicon oxynitride, and a low-k dielectric constant dielectric material. In some embodiments, the first mold layer 142 and the third mold layer 146 may include silicon nitride or silicon oxynitride, and the second mold layer 144 may include silicon oxide or a low-k dielectric constant dielectric material.

In embodiments, the cell transistor CTR may include an active pattern AP, a gate insulation layer 150, and a word line WL sequentially arranged on a sidewall of the mold structure 140.

In embodiments, the active pattern AP may include a vertical extension portion AP_V extending in the vertical direction Z on the sidewall of the mold structure 140 and a horizontal extension portion AP_P extending in the second horizontal direction Y on the bottom of the vertical extension portion AP_V. The horizontal extension portion AP_P may be directly arranged on the top surface of the anti-oxidation film pattern AL.

In embodiments, the active pattern AP arranged between two adjacent mold structures 140 may have a U-shaped vertical cross section. For example, the vertical extension portion AP_V arranged on the sidewall of the first mold structure of the two adjacent mold structures 140 may be a channel region of the first cell transistor CTR1, and the vertical extension portion AP_V arranged on the sidewall of the second mold structure of the two adjacent mold structures 140 may be a channel region of the second cell transistor CTR2.

In embodiments, the active pattern AP may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), or zirconium zinc tin oxide (ZrₓZn_{y}Sn_{z}O).

In embodiments, a gate insulation layer 150 may be arranged on the active pattern AP. The gate insulation layer 150 may be arranged on a sidewall of the vertical extension portion AP_V and a top surface of the horizontal extension portion AP_P, and the gate insulation layer 150 arranged between two adjacent mold structures 140 may have a U-shaped vertical cross-section. The gate insulation layer 150 may include a first portion 150_V and a second portion 150_P, the first portion 150_V may be arranged on a sidewall of the vertical extension portion AP_V, and the second portion 150_P may be arranged on a top surface of the horizontal extension portion AP_P.

In embodiments, the gate insulation layer 150 may include at least one selected from a high-k dielectric material having a dielectric constant higher than that of silicon oxide, or a ferroelectric material. In some embodiments, the gate insulation layer 150 may be formed of at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconium titanium oxide (PbZrTiO), strontium tantalum bismuth oxide (StTaBiO), bismuth iron oxide (BiFeO), strontium titanium oxide (SrTiO), yttrium oxide (YO), aluminum oxide (AlO), or lead scandium tantalum oxide (PbScTaO).

The word lines WL may be arranged on the sidewall of the gate insulation layer 150. In some embodiments, the word line WL may include Ti, TiN, Ta, TaN, Mo, Ru, W, WN, TiSiN, WSiN, polysilicon, or a combination thereof. For example, two word lines WL may be spaced apart from each other between two adjacent mold structures 140 and extend in the first horizontal direction X. For example, a first word line WL1 and a second word line WL2 may be spaced apart from each other between two adjacent mold structures 140. A bottom surface of the word line WL may be arranged on the second portion 150_P of the gate insulation layer 150.

An insulating liner 162 and a buried insulation layer 164 may be arranged between the first word line WL1 and the second word line WL2. The insulating liner 162 may be conformally arranged on the upper sidewall of the first portion 150_V of the gate insulation layer 150 and the upper surface of the second portion 150_P thereof, and on the sidewalls and top surfaces of the first word line WL1 and the second word line WL2. The buried insulation layer 164 may be arranged on the insulation liner 162.

A plurality of landing pads 170 may be arranged on the plurality of cell transistors CTR, respectively. An upper insulation layer 172 may be arranged on the sidewalls of the plurality of landing pads 170 and on the top surface of the mold structure 140. The cell capacitors CAP may be arranged on the landing pads 170, respectively. The plurality of landing pads 170 may include Ti, TiN, Ta, TaN, W, WN, TiSiN, WSiN, polysilicon, or a combination thereof. The cell capacitors CAP may have a metal-insulator-metal type capacitor structure. For example, each of the cell capacitors CAP may include a first electrode, a second electrode, and a capacitor dielectric layer arranged between the first electrode and the second electrode.

In the semiconductor device 100 according to embodiments described with reference to FIGS. 1 to 7, since the anti-oxidation film pattern AL covers the entirety of the top surface BL_u of the bit line BL and extends in the second horizontal direction Y, oxidation of the bit line BL that may occur in the process of forming the active pattern AP if the anti-oxidation film pattern AL were not present may be prevented and/or reduced. In addition, the presence of oxygen vacancies in the anti-oxidation film pattern AL may reduce the contact resistance between the bit line BL and the active pattern AP.

An electrical performance test for a semiconductor device according to embodiments of the present disclosure has been performed. A semiconductor device according to an embodiment has a structure further including an anti-oxidation film pattern including indium oxide (In_{0.42}O_{0.58}), and a semiconductor device according to a comparative example has a structure that does not include an anti-oxidation film pattern. In both the embodiment and the comparative example, indium gallium zinc oxide containing indium, gallium, and zinc in a 1:1:1 ratio was included as semiconductor patterns or channel regions.

The semiconductor device according to the embodiments exhibited a cell operating current that was 2.6 times higher than that of the comparative example, indicating that the carrier mobility in the channel was increased by two times or more in the embodiment. In addition, the semiconductor device according to the embodiments showed a 26% decrease in contact resistance compared to the comparative example and/or a 71% decrease in channel resistance compared to the comparative example. This indicates that the insertion of the anti-oxidation film pattern in embodiments may reduce a total electrical resistance between the bit line and the active pattern and increase the operating current of the entirety of the semiconductor device. Therefore, the semiconductor device 100 may have excellent electrical performance.

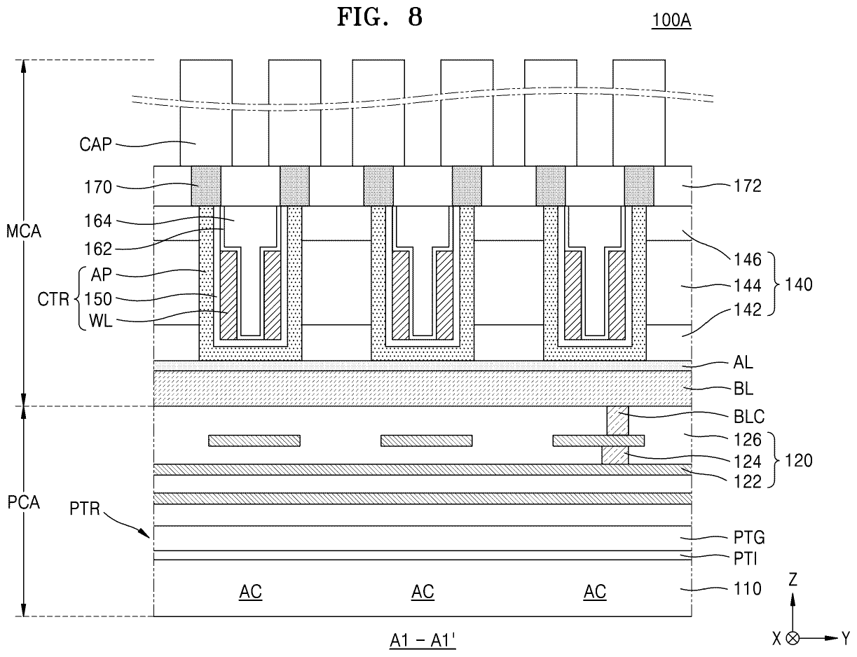

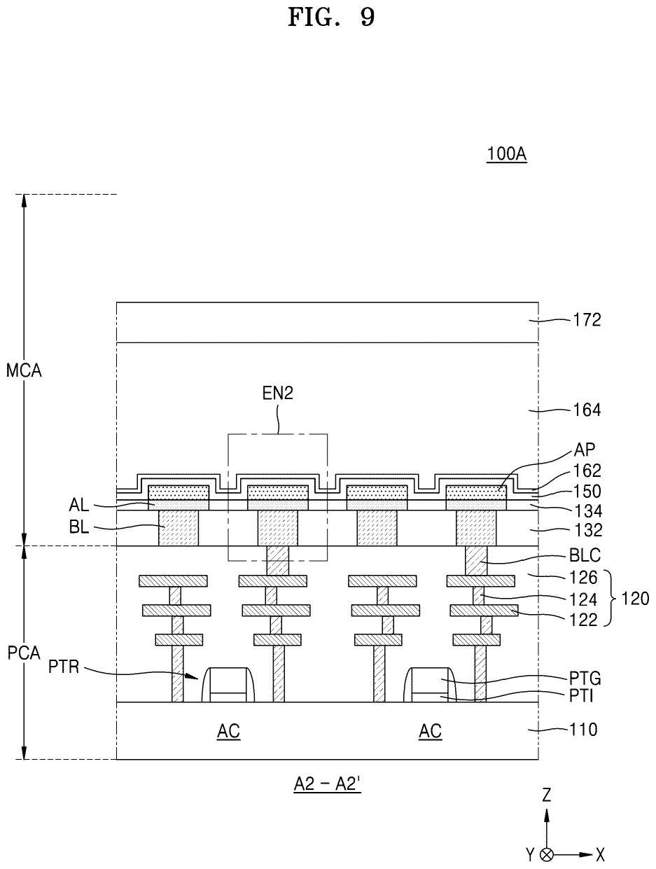

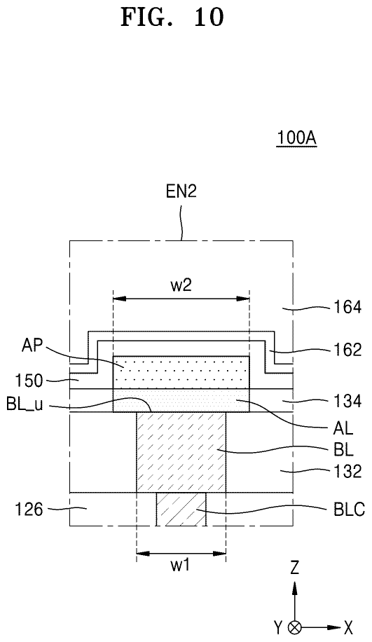

FIGS. 8 and 9 are cross-sectional views illustrating a semiconductor device 100A according to embodiments. FIG. 10 is an enlarged view of a portion EN2 of FIG. 9.

Referring to FIGS. 8 to 10, the plurality of bit lines BL may have a first width w1, an anti-oxidation film pattern AL may have a second width w2, and the second width w2 may be greater than the first width w1. The first insulation layer 132 may be arranged between the plurality of bit lines BL, and the anti-oxidation film pattern AL may be arranged on the top surface BL_u of each bit line BL and the top surface of the first insulation layer 132. A second insulation layer 134 may be formed on a top surface of the first insulation layer 132 and may be arranged on a sidewall of the anti-oxidation film pattern AL. In embodiments, the plurality of bit lines BL may be formed, the first insulation layer 132 may be formed to fill a space between the plurality of bit lines BL, and the anti-oxidation film pattern AL may be formed on the bit lines BL and the first insulation layer 132.

In embodiments, as the anti-oxidation film pattern AL has a larger width than the bit line BL and is formed to cover the entirety of the top surface BL_u of the bit line BL, oxidation of the bit line BL in the process of forming the active pattern AP may be prevented and/or reduced.

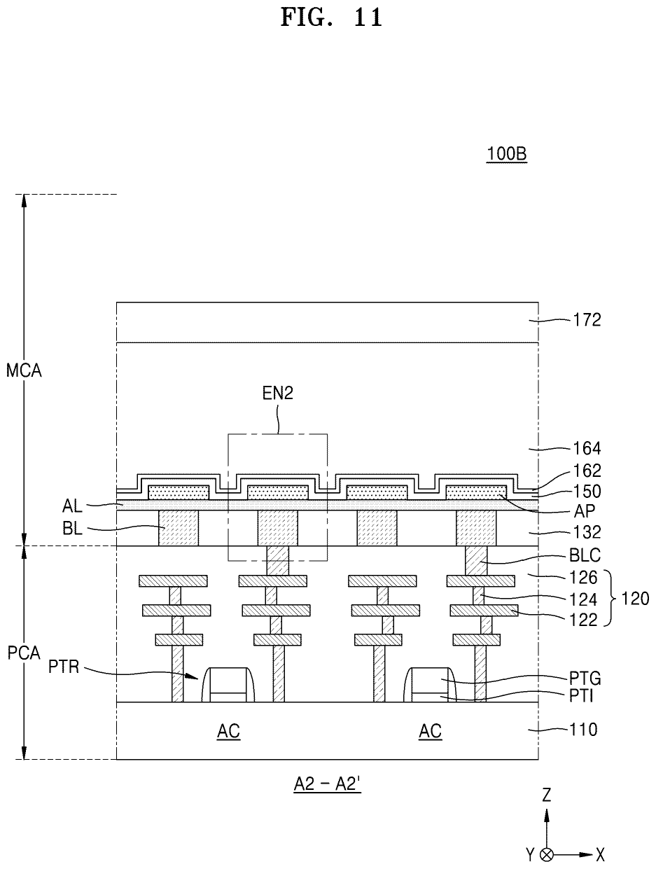

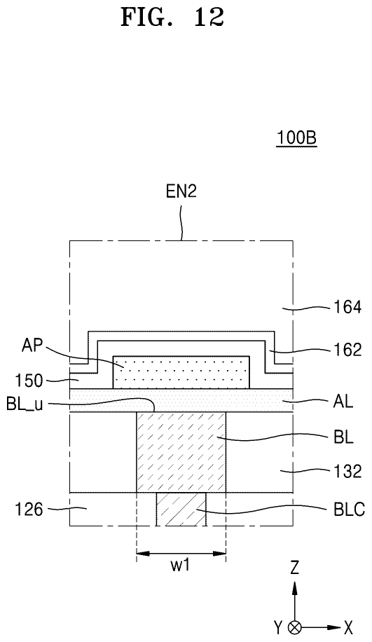

FIG. 11 is a cross-sectional view illustrating a semiconductor device 100B according to embodiments. FIG. 12 is an enlarged view of a portion EN2 of FIG. 11.

Referring to FIGS. 11 and 12, the anti-oxidation film pattern AL may cover top surfaces of the plurality of bit lines BL and the first insulation layer 132 and may extend in the first horizontal direction X and the second horizontal direction Y. In embodiments, as the anti-oxidation film pattern AL is formed to cover the entirety of the top surface BL_u of the bit line BL, oxidation of the bit line BL in the process of forming the active pattern AP may be prevented and/or reduced.

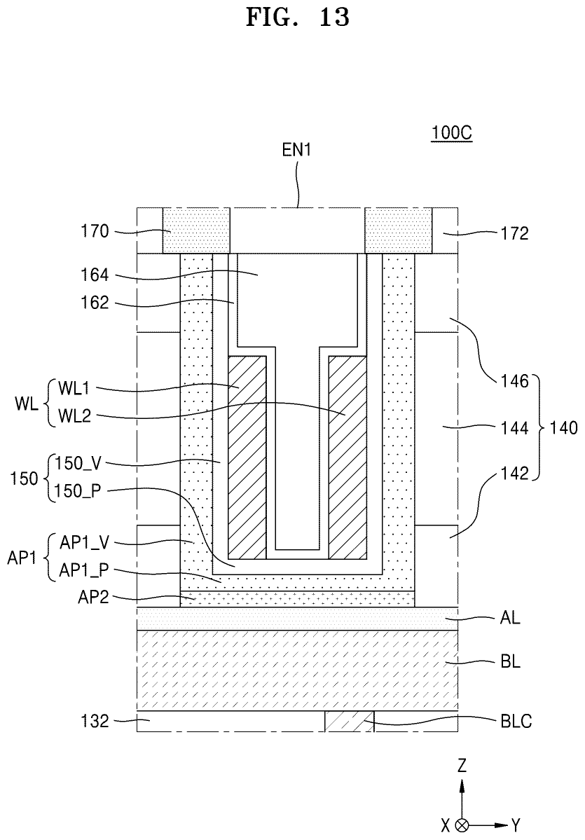

FIG. 13 is a cross-sectional view illustrating a semiconductor device 100C according to embodiments.

Referring to FIG. 13, the active pattern AP may include a first portion AP1 and a second portion AP2. The first portion AP1 may include a vertical extension portion AP1_V and a horizontal extension portion AP1_P, and may have a U-shaped vertical cross section. The second portion AP2 may be arranged between a bottom surface of the horizontal extension portion AP1_P and the anti-oxidation film pattern AL. The second portion AP2 may have a bar-shaped vertical cross section.

In embodiments, the first portion AP1 may include an oxide semiconductor having a composition different from that of the second portion AP2. In embodiments, the first portion AP1 and the second portion AP2 may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), or zirconium zinc tin oxide (ZrₓZn_{y}Sn_{z}O).

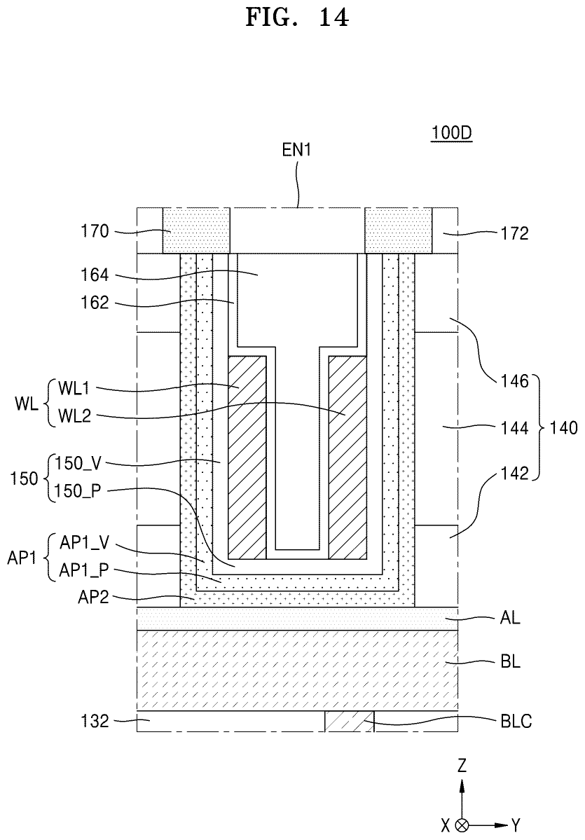

FIG. 14 is a cross-sectional view illustrating a semiconductor device 100D according to embodiments.

Referring to FIG. 14, the active pattern AP may include a first portion AP1 and a second portion AP2. The first portion AP1 may include a vertical extension portion AP1_V and a horizontal extension portion AP1_P, and may have a U-shaped vertical cross section. The second portion AP2 may be arranged between a bottom surface of the horizontal extension portion AP1_P and the anti-oxidation film pattern AL and between the sidewall of the vertical extension portion AP1_V and the sidewall of the mold structure 140. The second portion AP2 may have a U-shaped vertical cross section. In embodiments, the first portion AP1 may include an oxide semiconductor having a composition different from that of the second portion AP2.

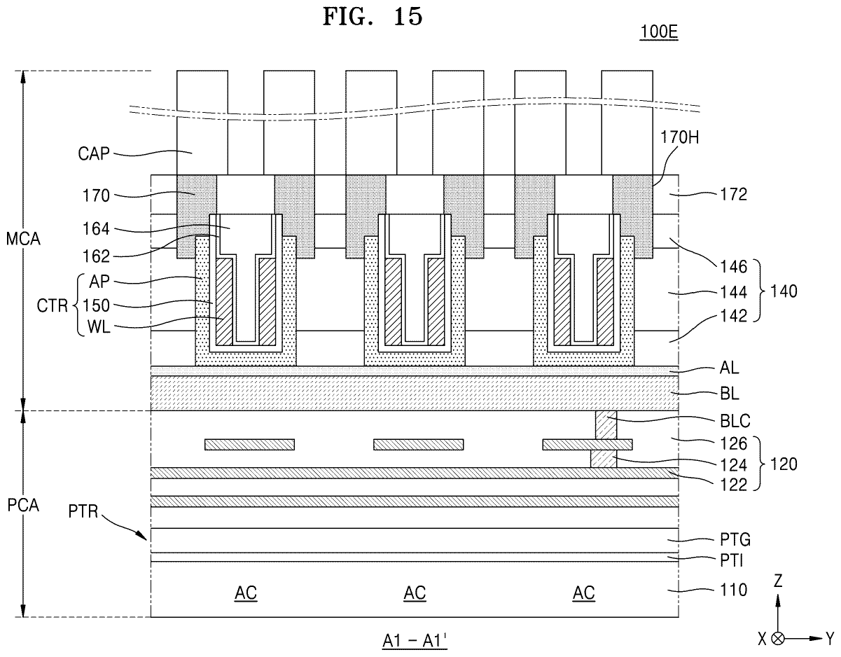

FIG. 15 is a cross-sectional view illustrating a semiconductor device 100E according to embodiments.

Referring to FIG. 15, the top surface of the active pattern AP may be arranged at a lower level than the top surface of the gate insulation layer 150. In embodiments, the landing pad opening 170H may be formed by removing a portion of the mold structure 140, and the landing pad 170 may be arranged within the landing pad opening 170H.

In embodiments, a portion of the landing pad 170 may extend to a level lower than the top surface of the active pattern AP, and the landing pad 170 may be in contact with the top surface of the active pattern AP and the upper side of the sidewall of the active pattern AP. As a portion of the landing pad 170 extends to a lower level than the top surface of the active pattern AP, a relatively large contact area between the landing pad 170 and the active pattern AP may be secured.

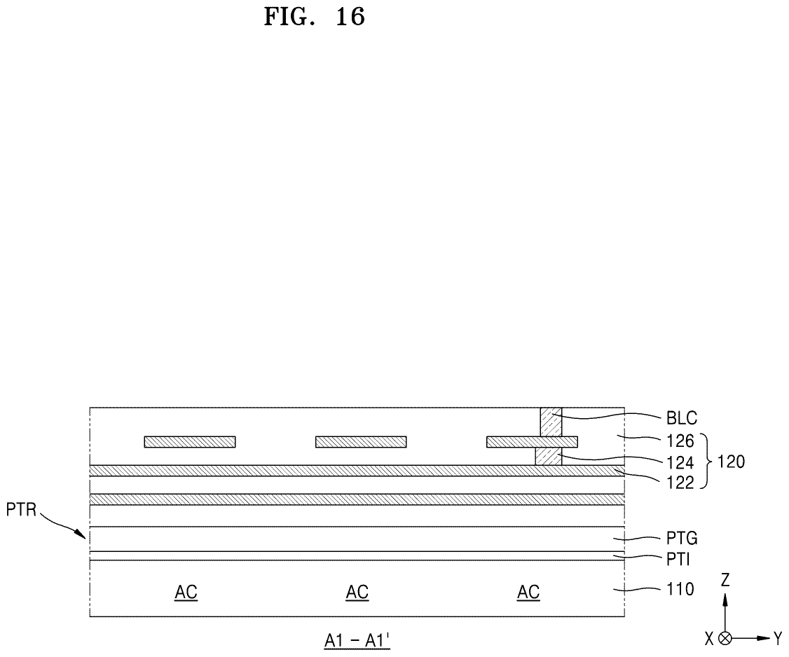

FIGS. 16, 17A, 17B, 17C, 18A, 18B, 18C, 19A, 19B, 19C, 20A, 20B, 21A, 21B, 22A, 22B, 23A, 23B, 23C, 24A, 24B, and 24C are schematic diagrams illustrating a method of manufacturing a semiconductor device 100 according to embodiments. Specifically, FIGS. 16, 17A, 18A, 19A, 20A, 21A, 22A, 23A, and 24A are cross-sectional views taken along line A1-A1′ of FIG. 2, FIGS. 17B, 18B, 19B, 20B, 21B, 22B, 23B, and 24B are cross-sectional views taken along line A 2-A2′ of FIG. 2, and FIGS. 17C, 18C, 19C, 23C, and 24C are plan views corresponding to the cross-sectional views of FIGS. 17A, 18A, 19A, 23A, and 24A, respectively.

Referring to FIG. 16, an active region AC may be formed on the substrate 110, and a peripheral circuit transistor PTR may be formed on the active region AC. For example, the peripheral circuit transistor PTR may include a gate electrode PTG and a gate insulation layer PTI.

Thereafter, a peripheral circuit wiring 122 and a peripheral circuit contact 124 electrically connected to the substrate 110 and the peripheral circuit transistor PTR may be formed, and a peripheral circuit insulation layer 126 covering the peripheral circuit wiring 122 and the peripheral circuit contact 124 may be formed above the substrate 110. The peripheral circuit insulation layer 126 may be formed using an oxide film, a nitride film, a low-k dielectric film, or a combination thereof.

The peripheral circuit contact 124 formed on the uppermost portion of the peripheral circuit contacts 124 may be referred to as a bit line contact BLC. The top surface of the bit line contact BLC may be arranged on the same plane as the uppermost surface of the peripheral circuit insulation layer 126.

Referring to FIGS. 17A to 17C, a bit line material layer BLM and an anti-oxidation film material layer ALM may be sequentially formed on the peripheral circuit insulation layer 126.

In embodiments, the bit line material layer BLM may be formed using a chemical vapor deposition process or an atomic layer deposition (ALD) process. The bit line material layer BLM may include Ti, TiN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof.

In embodiments, the anti-oxidation film material layer ALM may include an indium-rich oxide semiconductor. For example, the indium-rich oxide semiconductor may refer to an oxide containing indium in a relatively high content, and may include an oxide semiconductor containing indium, gallium, and/or zinc as cations. For example, the indium-rich oxide semiconductor may contain indium as an essential constituent cation and may selectively contain gallium and zinc. In embodiments, the anti-oxidation film material layer ALM may include an oxide represented by chemical formula of InₓGa_{y}Zn_{z}O_{1.5} (0.9≤x≤1, 0≤y≤0.1, 0≤z≤0.1, and x+y+z=1).

In embodiments, a first dopant may be included in the indium-rich oxide semiconductor in the process of forming the anti-oxidation film material layer ALM. In embodiments, the first dopant may include at least one of magnesium (Mg), tantalum (Ta), fluorine (F), or nitrogen (N). In some embodiments, a second dopant may be included in the indium-rich oxide semiconductor in the process of forming the anti-oxidation film material layer ALM in addition to the first dopant. The second dopant may or may not be the same material with the first dopant, and may include at least one of magnesium (Mg), tantalum (Ta), fluorine (F), or nitrogen (N).

In embodiments, the anti-oxidation film material layer ALM may be formed using a physical vapor deposition (PVD) process. In embodiments, the anti-oxidation film material layer ALM may be formed by a PVD process such as a sputtering process using a sputtering target including an oxide having a composition required to be included in the anti-oxidation film material layer ALM.

In embodiments, the anti-oxidation film material layer ALM may be formed by a PVD process such as a sputtering process or the like using a sputtering target including an oxide represented by a formula of [InₓGa_{y}Zn_{z}O_{1.5}]₁₋ᵤXᵤ (0.9≤x≤1, 0≤y≤0.1, 0≤z≤0.1, x+y+z=1, X is at least one of Mg, Ta, F, or N, and 0<u≤0.1).

In exemplary embodiments, the anti-oxidation film material layer ALM may be formed by a co-sputtering method using two or more sputtering targets. For example, the anti-oxidation film material layer ALM may be formed using a first sputtering target including an oxide having a composition of InGaO, a second sputtering target including an oxide having a composition of InZnO, and a third sputtering target including a source material of a first dopant.

In embodiments, some elements of the first dopant, for example, nitrogen or fluorine, may be included in the sputtering target and provided in the process of forming the anti-oxidation film material layer ALM. In some other embodiments, some elements of the first dopant, for example nitrogen or fluorine, may be provided as a part of the carrier gas or a part of the reaction gas in the process of forming the anti-oxidizing film material layer ALM.

In embodiments, the anti-oxidation film material layer ALM may be formed using a sputtering target including an oxide of InGaZnO, in which case a carrier gas including at least one of nitrogen or ammonia may be supplied into a process chamber. Accordingly, a first dopant including nitrogen may be included in the anti-oxidation film material layer ALM.

In embodiments, the anti-oxidation film material layer ALM may be formed by a plasma enhanced atomic layer deposition (PE-ALD) process using a plasma source including at least one of nitrogen or ammonia.

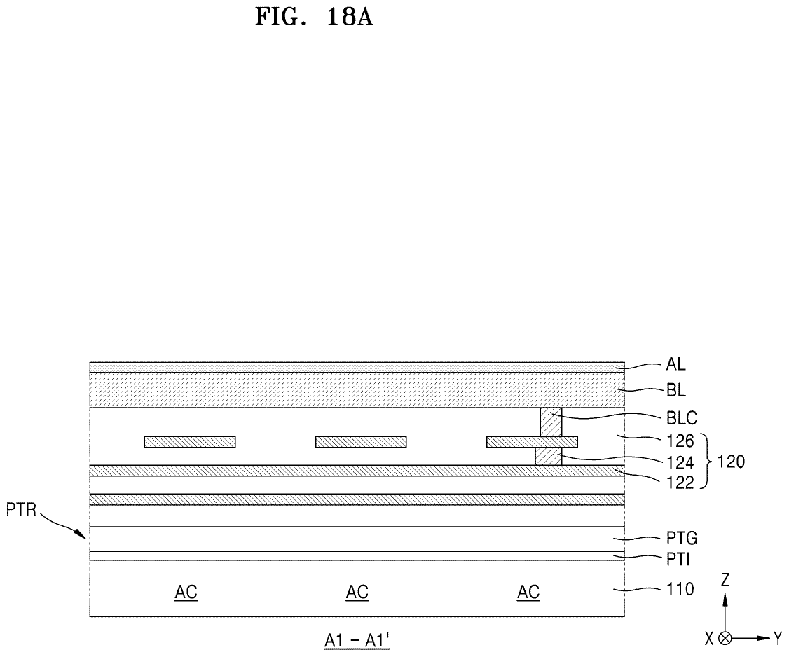

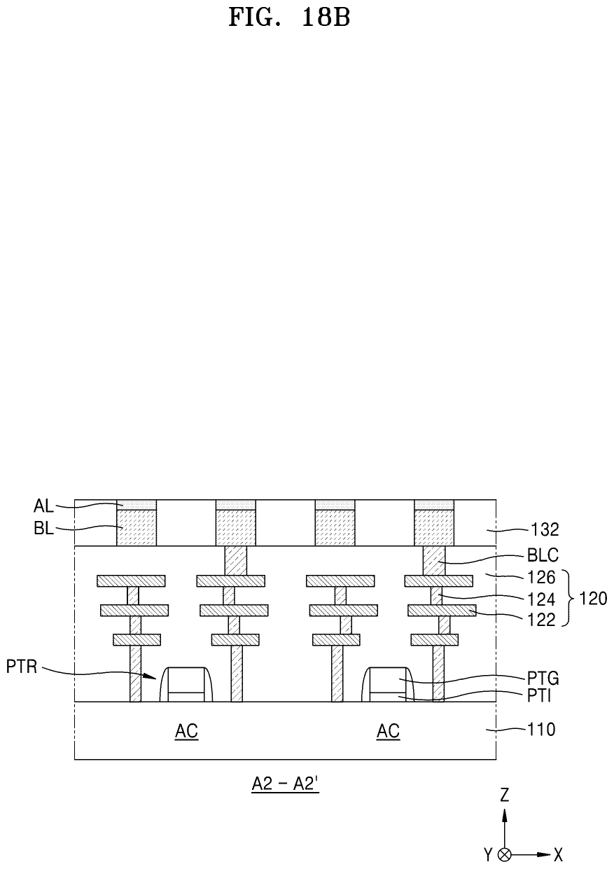

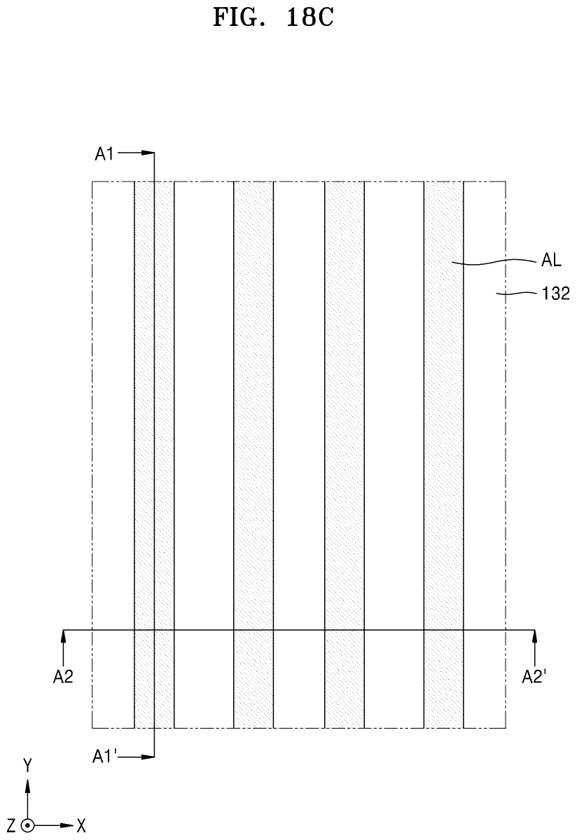

Referring to FIGS. 18A to 18C, a mask pattern may be formed on the anti-oxidation layer material layer ALM, and a plurality of anti-oxidation film patterns AL and a plurality of bit lines BL may be formed by patterning the anti-oxidation film material layer ALM and the bit line material layer BLM using the mask pattern. The plurality of anti-oxidation film patterns AL and the plurality of bit lines BL may have a shape of a line pattern extending in the second horizontal direction Y. Both sidewalls of the plurality of anti-oxidation film patterns AL may be aligned with both sidewalls of the plurality of bit lines BL.

Thereafter, a first insulation layer 132 filling a space between the plurality of anti-oxidation film patterns AL and between the plurality of bit lines BL may be formed. The first insulation layer 132 may be in contact with both sidewalls of the plurality of anti-oxidation film patterns AL and both sidewalls of the plurality of bit lines BL, and the first insulation layer 132 may have a top surface coplanar with the top surfaces of the plurality of anti-oxidation film patterns AL.

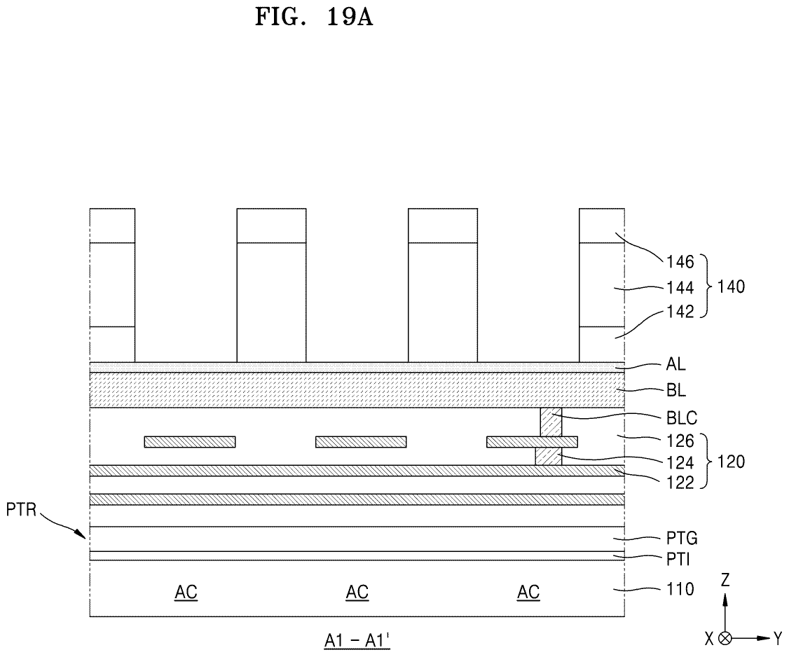

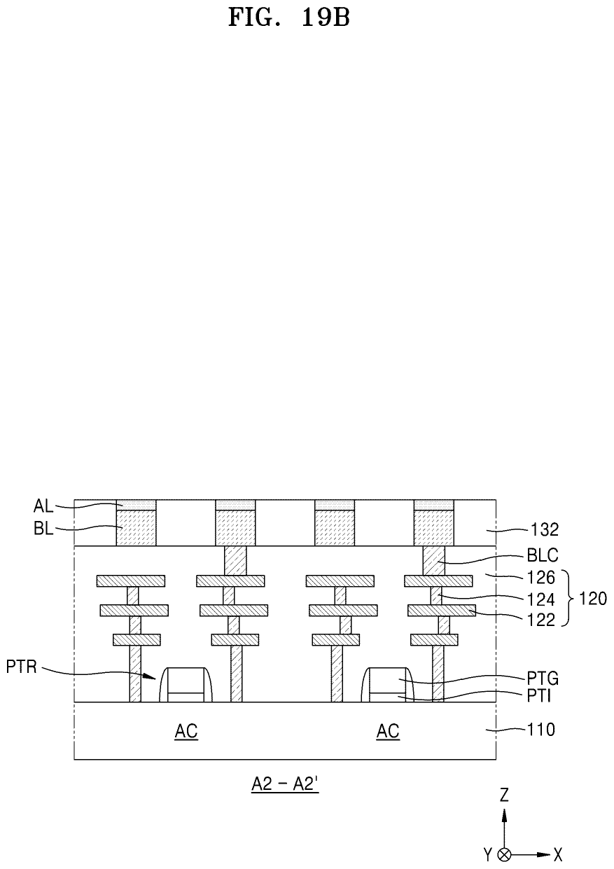

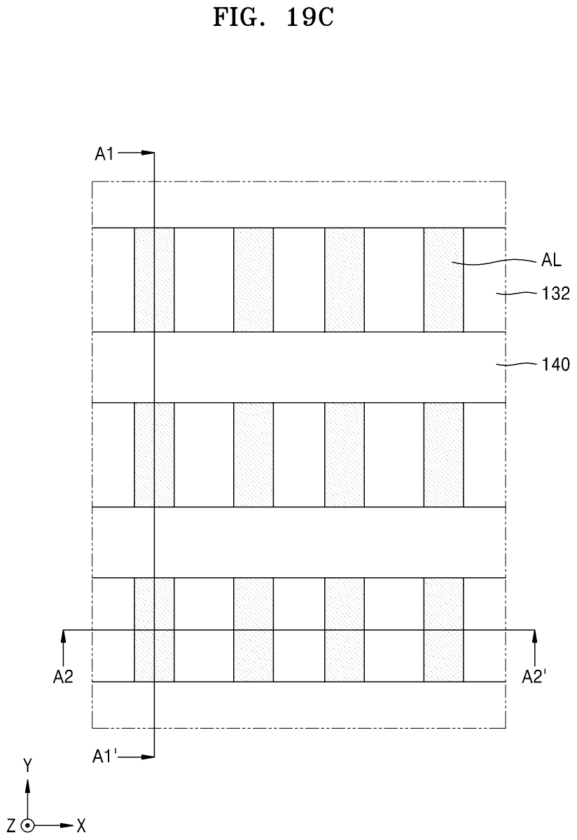

Referring to FIGS. 19A to 19C, a plurality of mold structures 140 extending in the first horizontal direction X may be formed on the top surfaces of the plurality of anti-oxidation film patterns AL and the first insulation layer 132. Each of the plurality of mold structures 140 may include a first mold layer 142, a second mold layer 144, and a third mold layer 146 sequentially stacked on the top surfaces of the plurality of anti-oxidation film patterns AL and the first insulation layer 132.

In embodiments, each of the first to third mold layers 142, 144, and 146 may include at least one of silicon oxide, silicon nitride, silicon oxynitride, and a low-k dielectric constant dielectric material. In some embodiments, the first mold layer 142 and the third mold layer 146 may include silicon nitride or silicon oxynitride, and the second mold layer 144 may include silicon oxide or a low-k dielectric constant dielectric material.

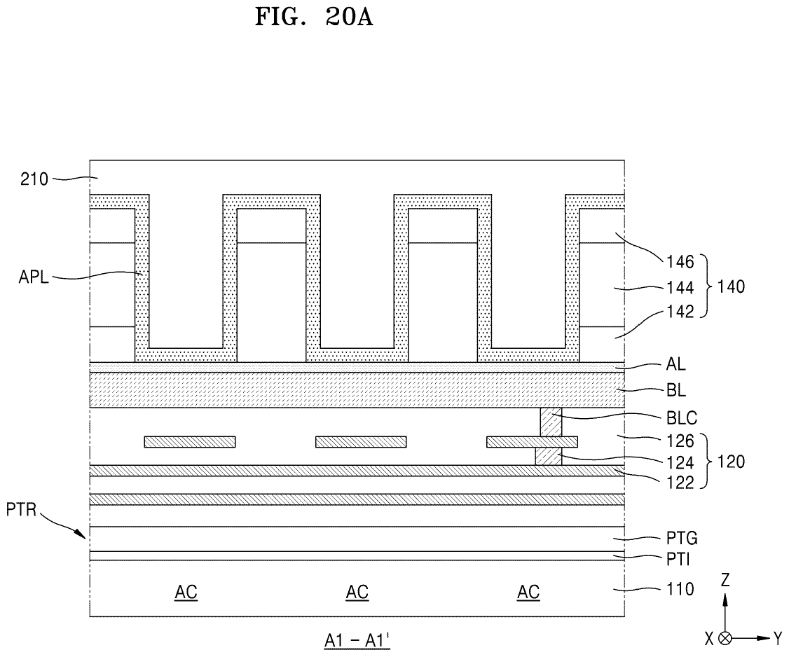

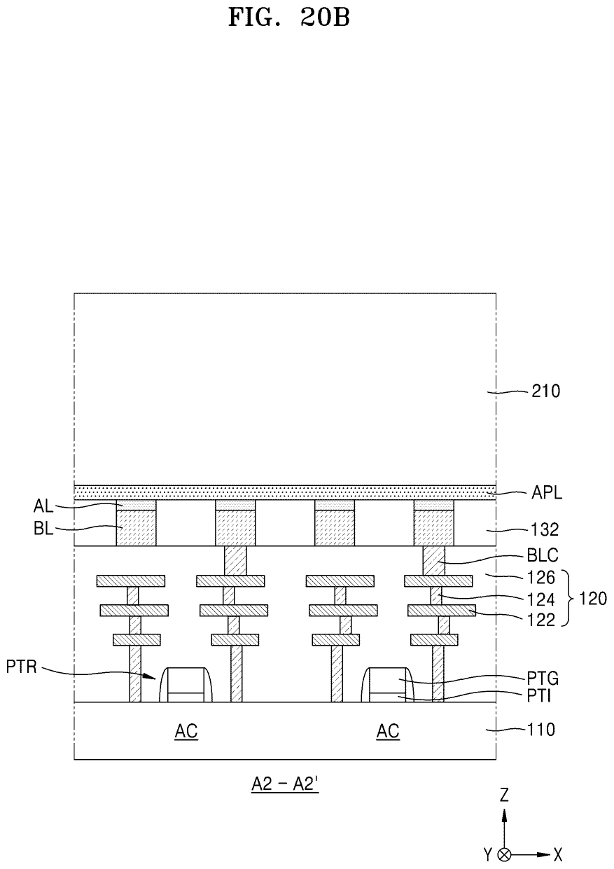

Referring to FIGS. 20A and 20B, an active material layer APL may be formed on the sidewalls and top surfaces of the mold structures 140. The active material layer APL may be conformally arranged on the sidewalls and the top surfaces of the mold structures 140, and on the top surfaces of the plurality of anti-oxidation film patterns AL and the first insulation layer 132.

In embodiments, the active material layer APL may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), or zirconium zinc tin oxide (ZrₓZn_{y}Sn_{z}O).

In embodiments, the active material layer APL may be formed by a chemical vapor deposition (CVD) process, a plasma enhanced chemical vapor deposition (PECVD) process, an atomic layer deposition (ALD) process, or a plasma enhanced atomic layer deposition (PEALD) process.

In embodiments, the active material layer APL may be formed by sequentially performing a deposition cycle of supplying a precursor including cations of an oxide semiconductor constituting the active material layer APL. For example, in order to form an active material layer APL containing indium gallium zinc oxide (InₓGa_{y}Zn_{z}O), a sub-cycle of indium precursor supply, a sub-cycle of gallium precursor supply, and a sub-cycle of zinc precursor supply may be sequentially performed, and each sub-cycle may be performed multiple times. In embodiments, in the process of forming the active material layer APL, O₂, O₃, H₂O, H₂O₂, oxygen plasma, or the like may be used as a reactant or an oxygen source.

In embodiments, in the process for forming the active material layer APL, the entirety of the top surfaces of the bit lines BL may be covered by the anti-oxidation film pattern AL and thus may not be exposed to an oxidation atmosphere caused by O₂, O₃, H₂O, H₂O₂, oxygen plasma, or the like. Accordingly, unwanted oxidation or damage of the bit lines BL that may occur without the anti-oxidation film pattern AL may be prevented.

Thereafter, a protective layer 210 may be formed on the active material layer APL with a thickness large enough to fill a space between the mold structures 140. In embodiments, the protective layer 210 may include a spin-on hardmask or a spin-on dielectric.

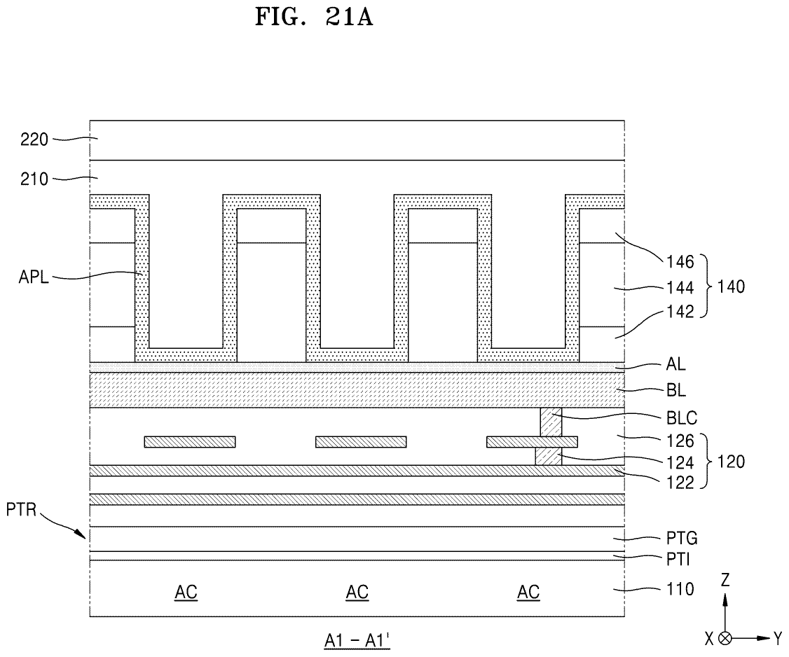

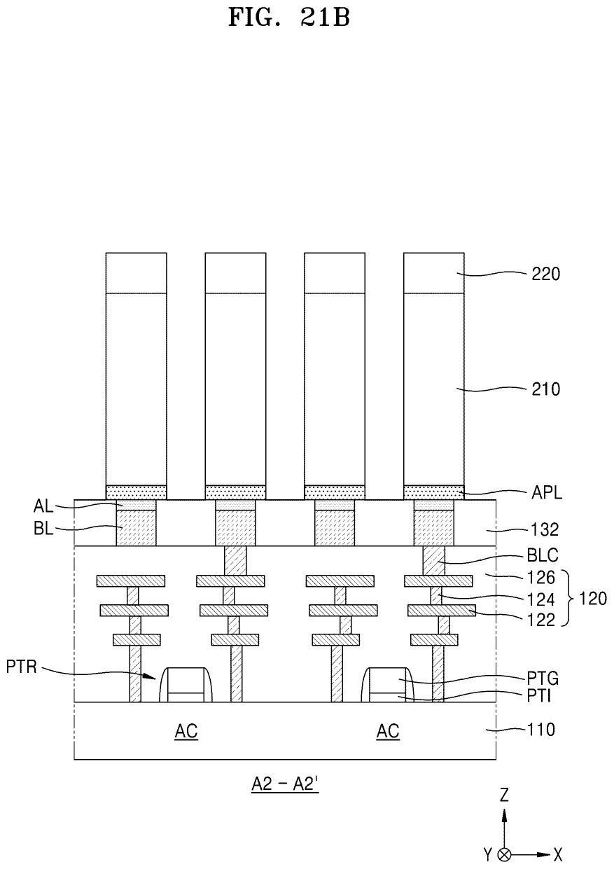

Referring to FIGS. 21A and 21B, a mask pattern 220 extending in the second horizontal direction Y may be formed on the protective layer 210. Thereafter, a portion of the protective layer 210 and a portion of the active material layer APL may be removed by using the mask pattern 220 as an etching mask. Accordingly, the active material layer APL may extend in the second horizontal direction Y along the top surfaces and the sidewalls of the mold structures 140.

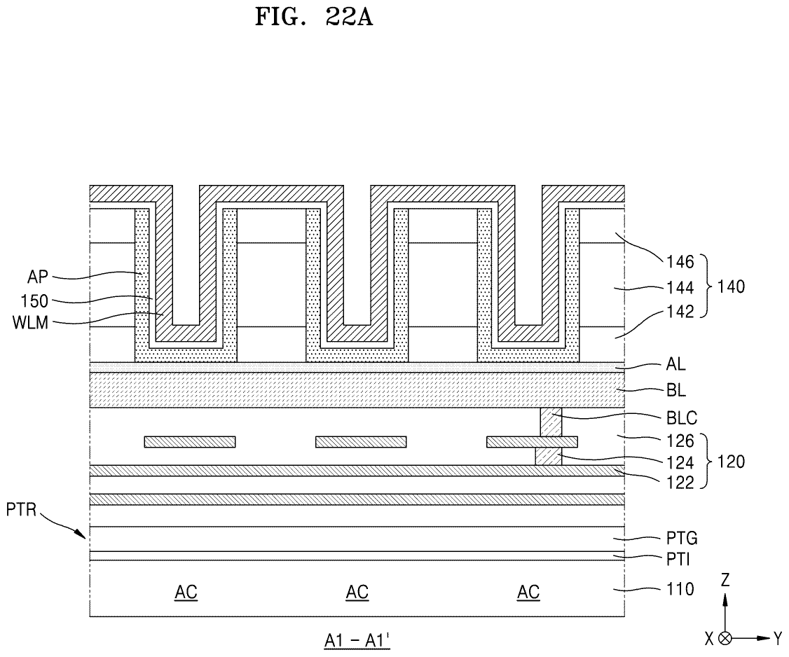

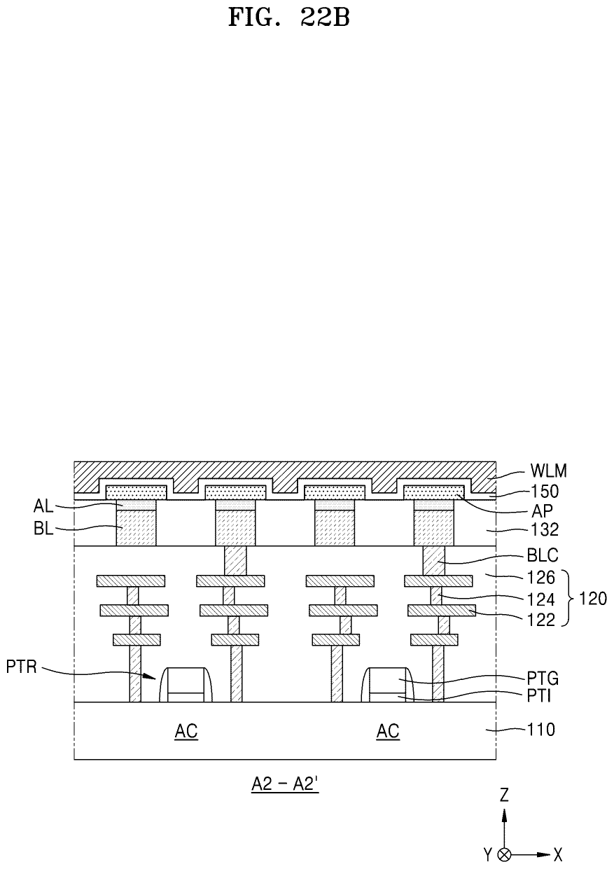

Referring to FIGS. 22A and 22B, the mask pattern 220 and the protective layer 210 may be removed. Thereafter, an anisotropic etching process or an etch-back process may be performed on a portion of the active material layer APL arranged on the top surfaces of the mold structures 140.

In embodiments, a portion of the active material layer APL arranged on the top surfaces of the mold structures 140 may be removed by the anisotropic etching process or the etch-back process, and a portion of the active material layer APL arranged on the sidewalls of the mold structures 140 and a portion of the active material layer APL arranged between the two adjacent mold structures 140 may remain. The active material layer APL remaining after the anisotropic etching process or the etch-back process will be referred to as an active pattern AP. The top surfaces of the mold structures 140 (e.g., the top surfaces of the third mold layers 146) may be exposed again by the anisotropic etching process or the etch-back process. The top surfaces of the mold structures 140 (e.g., the top surfaces of the third mold layers 146) may be arranged at the same level as the top surface of the active pattern AP.

In embodiments, one active pattern AP may be defined between two adjacent mold structures 140, and the one active pattern AP may have a U-shaped vertical cross section. In embodiments, the bottom portion (e.g., the horizontal extension portion AP_P) (see FIG. 5) of the active pattern AP may not be in direct contact with the bit lines BL, and may be in contact with the anti-oxidation film pattern AL arranged between the bottom portion of the active pattern AP and each of the bit lines BL.

Thereafter, a gate insulation layer 150 and a word line material layer WLM may be sequentially formed on the mold structures 140 and the active pattern AP.

In embodiments, the gate insulation layer 150 may be conformally formed on the top surfaces of the mold structures 140, on the sidewall of the active pattern AP, and on the top surface of the first insulation layer 132. Thereafter, the word line material layer WLM may be conformally formed on the gate insulation layer 150.

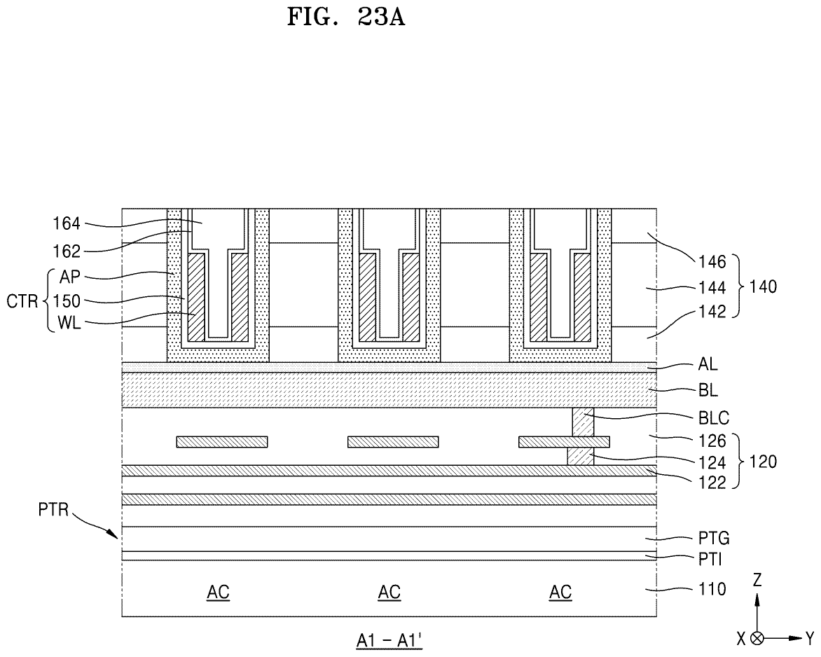

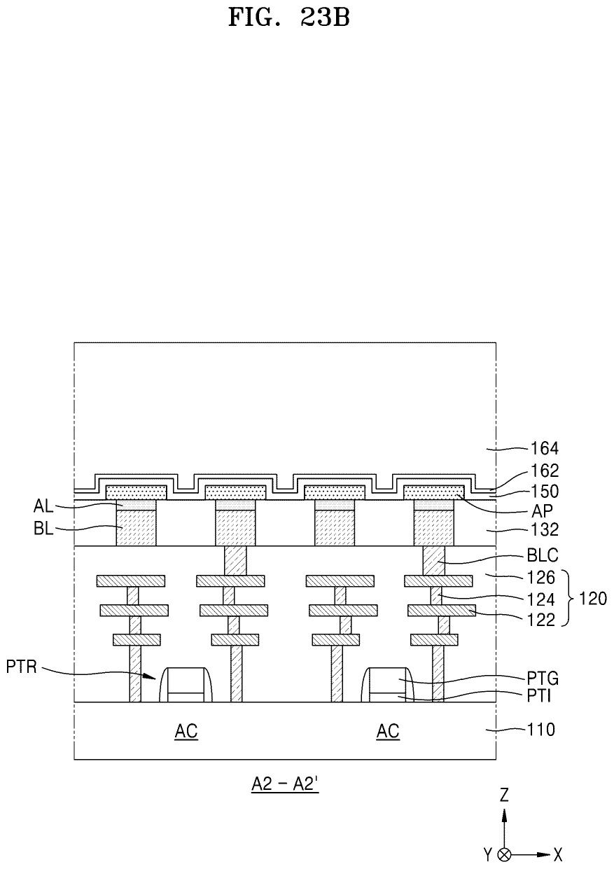

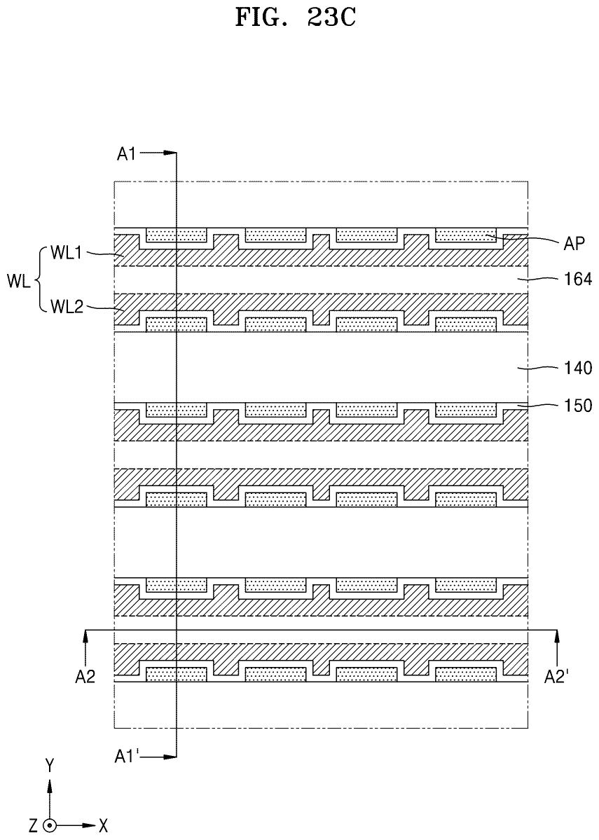

Referring to FIGS. 23A to 23C, an anisotropic etching process or a recess process may be performed on the word line material layer WLM to leave the word line WL only between the two mold structures 140 arranged adjacent to each other (e.g., only on the sidewall of the gate insulation layer 150).

In embodiments, an anisotropic etching process or a recess process may be applied to the upper side of the word line WL so that the top surface of the word line WL may be arranged at a lower level than the top surfaces of the active pattern AP and the gate insulation layer 150, and/or the top surfaces of the mold structures 140.

As a result of the anisotropic etching process or the recess process, as illustrated in FIG. 23C, a first word line WL1 may be arranged on a sidewall of one mold structure 140 of the two mold structures 140 which are adjacent to each other and a second word line WL2 may be arranged on a sidewall of the other mold structure 140 thereof. The top surface of the gate insulation layer 150 may be exposed between the first word line WL1 and the second word line WL2.

In embodiments, a portion of the gate insulation layer 150 arranged between the first word line WL1 and the second word line WL2 may not be removed by the anisotropic etching process or the recess process, and the gate insulation layer 150 may have a U-shaped vertical cross section.

In some embodiments, the anisotropic etching process or the recess process may be performed until a portion of the gate insulation layer 150 arranged between the first word line WL1 and the second word line WL2 is further removed, and in this case, a portion of the gate insulation layer 150 arranged under the first word line WL1 has an L shape, and may be physically spaced apart from a portion of the gate insulation layer 150 arranged under the second word line WL2.

Thereafter, the insulating liner 162 and the buried insulation layer 164 may be sequentially formed on the top surfaces of the mold structures 140. In example embodiments, the insulating liner 162 may be formed to have a relatively small thickness, and the buried insulation layer 164 may be formed to have a large thickness enough to fill the space between two adjacent mold structures 140.

Thereafter, a portion of the insulating liner 162, a portion of the buried insulation layer 164, and a portion of the gate insulation layer 150, which are arranged on the top surfaces of the mold structures 140 may be removed to expose the top surfaces of the mold structures 140 and the top surface of the active pattern AP again.

A process for removing a portion of the insulating liner 162 and a portion of the gate insulation layer 150 may be a grinding or chemical mechanical polishing (CMP) process, and after the grinding or CMP process, an upper surface of the buried insulation layer 164, a top surface of the gate insulation layer 150, a top surface of the active pattern AP, and a top surface of the mold structures 140 may be arranged on the same plane.

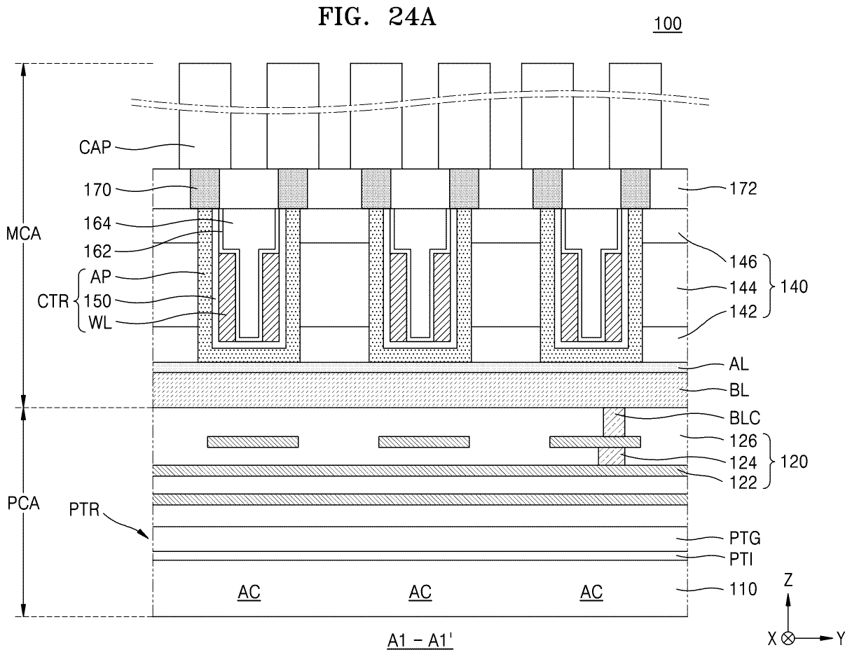

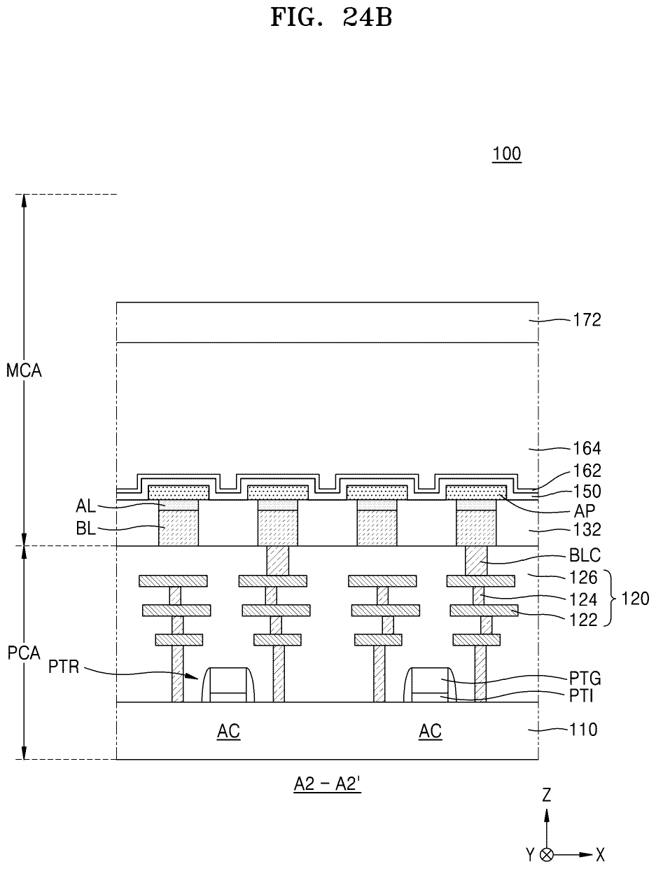

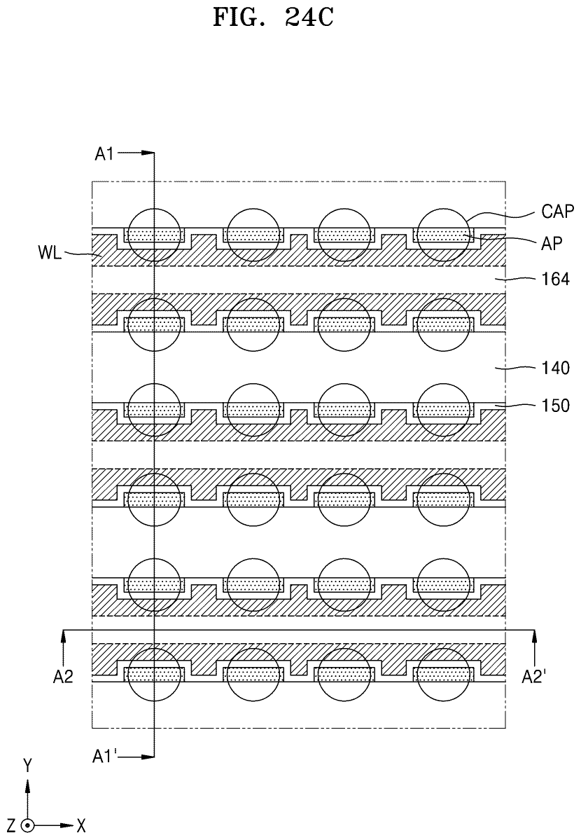

Referring to FIGS. 24A to 24C, landing pads 170 and an upper insulation layer 172 covering the sidewalls of the landing pads 170 may be formed on the mold structures 140. Each of the landing pads 170 may be formed to have a bottom surface in contact with the top surface of the active pattern AP.

In some embodiments, a portion of each of the mold structures 140 may be removed to form a landing pad recess 170H (see FIG. 15) exposing a portion of the top surface and the sidewall of the active pattern AP, and the landing pad 170 in contact with a portion of the top surface and the sidewall of the active pattern AP may be formed in the landing pad recess 170H. In this case, the semiconductor device 100E described with reference to FIG. 15 may be formed.

Then, a cell capacitor CAP may be formed on each of the landing pads 170.

The semiconductor device 100 may be completely formed by performing the above-described process.

According to embodiments, the anti-oxidation film pattern AL may cover the top surfaces of the bit lines BL, and the metal material included in the bit lines BL may be prevented from being oxidized in the process of forming the active pattern AP including the oxide semiconductor. The semiconductor device 100 may have a relatively low contact resistance and a relatively high operating current. Therefore, the semiconductor device 100 may have excellent electrical performance.

In the embodiments described above, it has been described that the bit lines BL and the anti-oxidation film pattern AL are patterned in the same process with reference to FIGS. 17A, 17B, 17C, 18A, 18B, and 18C. However, in other embodiments, the bit line material layer BLM may be formed first, the mask pattern may be formed on the bit line material layer BLM, the bit line material layer BLM is patterned to form the bit lines BL, and the first insulation layer 132 may be formed to fill a space between the plurality of bit lines BL. Thereafter, the anti-oxidation layer ALM may be formed to cover the bit lines BL, the mask pattern may be formed on the anti-oxidation film material layer ALM, and the anti-oxidation film material layer ALM may be patterned to form the anti-oxidation film pattern AL. In these embodiments, the second width w2 of the anti-oxidation film pattern AL may be different from the first width w1 of each of the bit lines BL. For example, the second width w2 of the anti-oxidation film pattern AL may be greater than the first width w1 of each bit line BL, and the top surfaces of the bit lines BL may be completely covered in the process of forming the active pattern AP. In this case, the semiconductor device 100A described with reference to FIGS. 8 to 10 may be manufactured.

In some other embodiments, the first insulation layer 132 filling a space between the plurality of bit lines BL is formed first, and the anti-oxidation layer ALM is formed to cover the bit lined BL and the first insulation layer 132, and then the patterning process for the anti-oxidation layer ALM may be omitted. The anti-oxidation layer material layer ALM may remain in a form of a continuous layer extending in the horizontal direction at a position vertically overlapping the plurality of bit lines BL. In this case, the semiconductor device 100B described with reference to FIGS. 11 and 12 may be manufactured.

In the embodiments described above, referring to FIG. 20A, and 20B, it has been described that the active material layer APL is formed as a single layer. However, in other embodiments, a first active material layer and a second active material layer with different compositions may be sequentially formed, and in this case, the semiconductor device 100C described with reference to FIG. 13 or the semiconductor device 100D described with reference to FIG. 14 may be manufactured.

According to some embodiments of the present disclosure, the anti-oxidation film pattern may cover the top surfaces of the bit lines, and the metal material included in the bit lines may be prevented from being oxidized in the process of forming the active pattern including the oxide semiconductor. Due to the structure in which the anti-oxidation film pattern is arranged between the active pattern and each of the bit lines, the semiconductor device may have a relatively low contact resistance and a relatively high operating current. Therefore, the semiconductor device may have excellent electrical performance.

While the present disclosure has been particularly shown and described with reference to embodiments thereof, it will be understood that various changes in form and details may be made therein without departing from the spirit and scope of the following claims.

What is claimed is:

1. A semiconductor device comprising:
bit lines arranged on a substrate and extending in a first horizontal direction;
an active pattern extending in a vertical direction on each of the bit lines and including a first end facing the bit lines and a second end opposite to the first end;
a cell capacitor arranged on the second end of the active pattern; and
an anti-oxidation film pattern arranged between the first end of the active pattern and each of the bit lines and extending in the first horizontal direction on a top surface of each of the bit lines, wherein:
the anti-oxidation film pattern includes an oxide semiconductor including indium and a first dopant, and
the first dopant includes at least one of magnesium (Mg), tantalum (Ta), fluorine (F), or nitrogen (N).

2. The semiconductor device of claim 1, wherein:
the oxide semiconductor included in the anti-oxidation film pattern comprises indium gallium zinc oxide,
a content of indium included in the oxide semiconductor is higher than a content of gallium included in the oxide semiconductor, and
a content of indium included in the oxide semiconductor is higher than a content of zinc included in the oxide semiconductor.

3. The semiconductor device of claim 1, wherein a constituent material of the anti-oxidation film pattern is represented by a chemical formula of [InₓGa_{y}Zn_{z}O_{1.5}]₁₋ᵤXᵤ, where 0.9≤x≤1, 0≤y≤0.1, 0≤z≤0.1, x+y+z=1, X is at least one of Mg, Ta, F, or N, and 0<u≤0.1.

4. The semiconductor device of claim 1, wherein the oxide semiconductor included in the anti-oxidation film pattern comprises indium oxide.

5. The semiconductor device of claim 1, wherein the oxide semiconductor included in the anti-oxidation film pattern comprises InₓO_{y} (0.38≤x≤0.42 and 0.58≤y≤0.62).

6. The semiconductor device of claim 1, wherein:
the anti-oxidation film pattern further includes oxygen vacancies, and
the oxygen vacancies are included in an amount of 1 to 19 atomic percent with respect to a total atomic content of components constituting the anti-oxidation film pattern.

7. The semiconductor device of claim 1, wherein:
the anti-oxidation film pattern covers the entirety of the top surfaces of the bit lines, and
a width of the anti-oxidation film pattern in a second horizontal direction crossing the first horizontal direction is greater than or equal to a width of each of the bit lines in the second horizontal direction.

8. The semiconductor device of claim 1, further comprising:
mold structures arranged on a first sidewall of the active pattern and extending in a second horizontal direction crossing the first horizontal direction;
word lines arranged on a second sidewall opposite to the first sidewall of the active pattern, and extending in the second horizontal direction; and
gate insulation layers arranged between the second sidewall of the active pattern and the word lines.

9. The semiconductor device of claim 8, wherein
a first portion of the anti-oxidation film pattern is arranged between a bottom surface of the first end of the active pattern and the top surface of each of the bit lines, and
a second portion of the anti-oxidation film pattern is arranged between a bottom surface of each of the mold structures and a top surface of each of the bit lines.

10. The semiconductor device of claim 9, wherein the active pattern comprises:
a vertical extension portion extending in the vertical direction on the sidewall of each of the mold structures; and
a horizontal extension portion connected to a bottom portion of the vertical extension portion and extending in the first horizontal direction, and
the first portion of the anti-oxidation film pattern is covered by a bottom surface of the vertical extension portion and a bottom surface of the horizontal extension portion.

11. The semiconductor device of claim 1, further comprising
a peripheral circuit arranged on the substrate, wherein
the bit lines are arranged at a higher vertical level than the peripheral circuit with respect to a top surface of the substrate, and
each of the bit lines is electrically connected to the peripheral circuit through a bit line contact.

12. A semiconductor device comprising:
a plurality of bit lines arranged on a substrate, extending parallel to each other, and extending in a first horizontal direction;
a plurality of anti-oxidation film patterns arranged on the plurality of bit lines, extending parallel to each other, and extending in the first horizontal direction;
a plurality of mold structures arranged on the plurality of anti-oxidation film patterns and extending in a second horizontal direction crossing the first horizontal direction;
a plurality of active patterns including a first end and a second end opposite to the first end, the first end being arranged on the sidewall of each of the plurality of mold structures and facing each of the anti-oxidation film patterns; and
a plurality of cell capacitors arranged on the second ends of the plurality of active patterns, respectively, wherein a constituent material of the anti-oxidation film pattern is represented by a chemical formula of [InₓGa_{y}Zn_{z}O_{1.5}]₁₋ᵤXᵤ, where 0.9≤x≤1, 0≤y≤0.1, 0≤z≤0.1, x+y+z=1, X is at least one of Mg, Ta, F, or N, and 0<u≤0.1.

13. The semiconductor device of claim 12, wherein each of the plurality of active patterns comprises:
a vertical extension portion extending in a vertical direction on a sidewall of each of the mold structures, and
a horizontal extension portion connected to a bottom portion of the vertical extension portion and extending in the first horizontal direction.

14. The semiconductor device of claim 13, further comprising:
word lines arranged on a sidewall of the vertical extension portion of each of the plurality of active patterns and on a top surface of the horizontal extension portion; and
gate insulation layers between the sidewall of the vertical extension portion of each of the plurality of active patterns and the word lines and between the top surface of the horizontal extension portion and each of the word lines.

15. The semiconductor device of claim 13, wherein
a first portion of the anti-oxidation film pattern is arranged between a bottom surface of the horizontal extension portion of each of the plurality of active patterns and a top surface of each of the plurality of bit lines, and
a second portion of the anti-oxidation film pattern is arranged between a bottom surface of each of the mold structures and the top surface of each of the plurality of bit lines.

16. The semiconductor device of claim 12, wherein
the anti-oxidation film pattern covers the entirety of the top surface of each of the plurality of bit lines, and
a width of the anti-oxidation film pattern in the second horizontal direction is greater than or equal to a width of each of the plurality of bit lines in the second horizontal direction.

17. The semiconductor device of claim 12, further comprising
a peripheral circuit arranged on the substrate, wherein
the plurality of bit lines are arranged at a higher vertical level than the peripheral circuit with respect to a top surface of the substrate, and
each of the plurality of bit lines is electrically connected to the peripheral circuit through a bit line contact.

18. A semiconductor device comprising:
a substrate;
a peripheral circuit arranged on the substrate;
bit lines that are arranged at a higher vertical level than the peripheral circuit on the substrate and extend in a first horizontal direction;
an active pattern that extends in a vertical direction on each of the bit lines and includes a first end facing the bit lines and a second end opposite to the first end;
a cell capacitor arranged on the second end of the active pattern; and
an anti-oxidation film pattern arranged between the first end of the active pattern and each of the bit lines and extending in the first horizontal direction on a top surface of each of the bit lines, wherein
a constituent material of the anti-oxidation film pattern is represented by a chemical formula of [InₓGa_{y}Zn_{z}O_{1.5}]₁₋ᵤXᵤ, where 0.9≤x≤1, 0≤y≤0.1, 0≤z≤0.1, x+y+z=1, X is at least one of Mg, Ta, F, or N, and 0<u≤0.1.

19. The semiconductor device of claim 18, further comprising:
mold structures arranged on a first sidewall of the active pattern and extending in a second horizontal direction crossing the first horizontal direction;
word lines arranged on a second sidewall opposite to the first sidewall of the active pattern, and extending in the second horizontal direction; and
gate insulation layers arranged between the second sidewall of the active pattern and the word lines, wherein
a first portion of the anti-oxidation film pattern is arranged between a bottom surface of the first end of the active pattern and the top surface of each of the bit lines, and
a second portion of the anti-oxidation film pattern is arranged between a bottom surface of each of the mold structures and the top surface of each of the bit lines.

20. The semiconductor device of claim 19, wherein the active pattern comprises
a vertical extension portion extending in the vertical direction on a sidewall of each of the mold structures,
a horizontal extension portion connected to a bottom portion of the vertical extension portion and extending in the first horizontal direction, and
the first portion of the anti-oxidation film pattern is covered by a bottom surface of the vertical extension portion and a bottom surface of the horizontal extension portion.
